(19) United States
(12) Patent Application Publication
(10) Pub. No.: US 2026/0076089 A1
(43) Pub. Date: Mar. 12, 2026

(54) METHOD FOR MANUFACTURING PHOTOELECTRIC CONVERSION ELEMENT, PHOTOELECTRIC CONVERSION ELEMENT, AND PHOTOELECTRIC CONVERSION MATERIAL

(71) Applicant: PANASONIC INTELLECTUAL PROPERTY MANAGEMENT CO., LTD., Osaka (JP)

(72) Inventor: Hiroko OKUMURA, Osaka (JP)

(73) Assignee: PANASONIC INTELLECTUAL PROPERTY MANAGEMENT CO., LTD., Osaka (JP)

(21) Appl. No.: 19/394,370

(22) Filed: Nov. 19, 2025

Related U.S. Application Data
(63) Continuation of application No. PCT/JP2024/018409, filed on May 17, 2024.

(30) Foreign Application Priority Data
May 23, 2023 (JP) 2023-084375

(51) Int. Cl. H10K 85/60; H10K 30/30; H10K 30/40; H10K 30/50; H10K 71/15

(52) U.S. Cl. CPC H10K 85/60; H10K 30/30; H10K 30/40; H10K 30/50; H10K 71/15

(57) ABSTRACT

A photoelectric conversion element manufacturing method of the present disclosure includes: forming a first electrode; forming a photoelectric conversion layer; and forming a second electrode. The forming of the photoelectric conversion layer includes: preparing a solution mixture by mixing a solution in which at least one selected from the group consisting of a phosphonium salt and a sulfonium salt is dissolved with a precursor solution of a perovskite compound; and forming a coating film using the solution mixture.

This application is a continuation of PCT/JP2024/018409 filed on May 17, 2024, which claims foreign priority of Japanese Patent Application No. 2023-084375 filed on May 23, 2023, the entire contents of both of which are incorporated herein by reference.

### BACKGROUND OF THE INVENTION

### 1. Field of the Invention

The present invention relates to a photoelectric conversion element manufacturing method, a photoelectric conversion element, and a photoelectric conversion material.

### 2. Description of Related Art

According to Energy Environ. Sci., 2022, volume 15, pp. 4201-4212 by Donglin Jia and four others, a technique is disclosed according to which CsPbI₃ quantum dots are produced and dissolved in a solvent, a sulfonium salt is added thereto to induce a reaction and the resulting solution is formed into a film shape to give a solar cell that includes the sulfonium salt filling a surface defect and thus has improved efficiency.

### SUMMARY OF THE INVENTION

The present disclosure aims to provide a new photoelectric conversion element capable of improving photoelectric conversion efficiency.

A photoelectric conversion element manufacturing method of the present disclosure includes:
forming a first electrode;
forming a photoelectric conversion layer; and
forming a second electrode, wherein
the forming of the photoelectric conversion layer includes:
   preparing a solution mixture by mixing a solution in which at least one selected from the group consisting of a phosphonium salt and a sulfonium salt is dissolved with a precursor solution of a perovskite compound; and
   forming a coating film using the solution mixture.

By the manufacturing method of the present disclosure, a new photoelectric conversion element capable of improving photoelectric conversion efficiency can be provided.

### BRIEF DESCRIPTION OF THE DRAWINGS

FIG. 1A shows a molecular structure of tributylmethylphosphonium iodide being an example of a quaternary phosphonium salt that can be used as a phosphonium salt in a photoelectric conversion element of a first embodiment.

FIG. 1B shows a molecular structure of tributylsulfonium iodide being an example of a tertiary sulfonium salt that can be used as a sulfonium salt in the photoelectric conversion element of the first embodiment.

FIG. 2 is a cross-sectional view schematically showing the configuration of a photoelectric conversion element 100 being an example of the photoelectric conversion element of the first embodiment.

FIG. 3 is a graph showing I-V characteristics of photoelectric conversion elements of Example 1, Example 2, and Comparative Example 1.

FIG. 4 is a graph showing open-circuit voltages of the photoelectric conversion elements of Example 1, Example 2, and Comparative Example 1.

FIG. 5 is a graph showing I-V characteristics of photoelectric conversion elements of Example 1, Example 3, and Comparative Example 1.

FIG. 6 is a graph showing open-circuit voltages of photoelectric conversion elements of Example 1, Example 3, Comparative Example 1, and Comparative Example 2.

FIG. 7 is a graph showing I-V characteristics of photoelectric conversion elements of Example 2, Example 4, Example 5, and Comparative Example 1.

FIG. 8 is a graph showing open-circuit voltages of photoelectric conversion elements of Example 2, Example 4, Example 5, Comparative Example 1, and Comparative Example 2.

FIG. 9 is a graph showing I-V characteristics of photoelectric conversion elements of Example 6, Example 7, and Comparative Example 1.

FIG. 10 is a graph showing open-circuit voltages of photoelectric conversion elements of Example 6, Example 7, Comparative Example 1, and Comparative Example 2.

FIG. 11 is a graph showing a photoluminescence (PL) spectrum of a photoelectric conversion layer alone formed from CsSnI₃+16 mol % SnF₂.

FIG. 12 is a graph showing a PL spectrum of a photoelectric conversion layer alone formed from CsSnI₃+16 mol % SnF₂+5 mol % tributylmethylphosphonium iodide.

FIG. 13 is a graph showing a PL spectrum of a photoelectric conversion layer alone formed from CsSnI₃+16 mol % SnF₂+5 mol % tributylsulfonium iodide.

FIG. 14 is a graph showing a PL lifetime of a photoelectric conversion layer alone formed from CsSnI₃+16 mol % SnF₂.

FIG. 15 is a graph showing a PL lifetime of a photoelectric conversion layer alone formed from CsSnI₃+16 mol % SnF₂+5 mol % tributylmethylphosphonium iodide.

FIG. 16 is a graph showing a PL lifetime of a photoelectric conversion layer alone formed from CsSnI₃+16 mol % SnF₂+5 mol % tributylsulfonium iodide.

FIG. 17 is a top-view scanning electron microscope (SEM) photograph of a photoelectric conversion layer formed from CsSnI₃+16 mol % SnF₂.

FIG. 18 is a top-view SEM photograph of a photoelectric conversion layer formed from CsSnI₃+16 mol % SnF₂+5 mol % tributylmethylphosphonium iodide.

FIG. 19 is a top-view SEM photograph of a photoelectric conversion layer formed from CsSnI₃+16 mol % SnF₂+5 mol % tributylsulfonium iodide.

### DETAILED DESCRIPTION

Embodiments of the present disclosure will be hereinafter described with reference to the drawings.

### First Embodiment

In a first embodiment, embodiments of the photoelectric conversion element manufacturing method and the photoelectric conversion element according to the present disclosure will be described.

A photoelectric conversion element produced by the manufacturing method of the first embodiment is a photoelectric conversion element including a first electrode, a photoelectric conversion layer, and a second electrode.

The manufacturing method of the first embodiment includes:
forming a first electrode;
forming a photoelectric conversion layer; and
forming a second electrode, wherein
the forming of the photoelectric conversion layer includes:
   preparing a solution mixture by mixing a solution in which at least one selected from the group consisting of a phosphonium salt and a sulfonium salt is dissolved with a precursor solution of a perovskite compound; and
   forming a coating film using the solution mixture.

A photoelectric conversion element having improved photoelectric conversion efficiency can be provided by the above manufacturing method.

The solution mixture prepared in the forming of the photoelectric conversion layer is a precursor solution of a material (hereinafter referred to as “photoelectric conversion material”) forming the photoelectric conversion layer. That is, in the forming of the photoelectric conversion layer, a precursor solution of a photoelectric conversion material is prepared, and a photoelectric conversion layer is formed from a coating film formed of the precursor solution of the photoelectric conversion material.

In the forming of the photoelectric conversion layer, the preparing of the above solution mixture may include, for example:

preparing: a first solution containing a compound including a monovalent cation and a halogen anion, a compound including a divalent cation and a halogen anion, and a solvent; a second solution containing a compound including a divalent cation and a F anion (fluoride anion) and a solvent; and a third solution containing the at least one selected from the group consisting of the phosphonium salt and the sulfonium salt and a solvent, and
mixing the second solution and the third solution with the first solution.

A photoelectric conversion element having further improved photoelectric conversion efficiency can be provided by the above manufacturing method.

The forming of the photoelectric conversion layer may further include baking the above coating film.

A photoelectric conversion element having further improved photoelectric conversion efficiency can be provided by the above manufacturing method.

As each of the solvents used in the forming of the photoelectric conversion layer, one solvent may be used, or a solvent mixture containing a plurality of solvents may be used. The solvent may be, for example, a solvent mixture containing dimethylformamide (DMF) and dimethyl sulfoxide (DMSO).

In the forming of the photoelectric conversion layer, for example, the mixed solution prepared is applied to a base by a coating technique, such as spin coating, and the resulting coating film is left to stand still for a given period of time for growth of a crystal nucleus in the coating film. This is followed by baking of the film obtained by the spin coating. When, for example, a solvent mixture containing DMF and DMSO (e.g., at a volume ratio of DMF:DMSO=1:4) is used, the coating film may be, for example baked at a temperature of approximately 120° C. or higher and approximately 220° C. or lower after a crystal nucleus is grown in the coating film at room temperature. In one example, the photoelectric conversion layer is obtained by growing a crystal nucleus in the coating film at room temperature and then baking the coating film, for example, at 120° C. for 1 minute, 160° C. for 1 minute, and then 200° C. for 10 minutes. In another example, the photoelectric conversion layer is obtained by growing a crystal nucleus in the coating film at room temperature and then baking the coating film, for example, at 50° C. for 3 minutes, 70° C. for 10 minutes, 120° C. for 1 minute, and then 160° C. for 10 minutes. Note that the above base serves as an underlayer in formation of the photoelectric conversion layer, and is, for example, adjacent to the photoelectric conversion layer in the photoelectric conversion element. When the photoelectric conversion layer is disposed on and in contact with the first electrode, the first electrode is the base.

A photoelectric conversion element of the first embodiment can be obtained, for example, by the manufacturing method according to the first embodiment. The photoelectric conversion element of the first embodiment includes the first electrode, the photoelectric conversion layer, and the second electrode, and the photoelectric conversion layer includes the perovskite compound and at least one selected from the group consisting of a phosphonium ion and a sulfonium ion.

The photoelectric conversion element of the first embodiment configured as above can improve the photoelectric conversion efficiency.

The photoelectric conversion layer of the photoelectric conversion element of the first embodiment includes, as described above, the perovskite compound and the at least one selected from the group consisting of the phosphonium ion and the sulfonium ion. For example, in the photoelectric conversion layer, the at least one selected from the group consisting of the phosphonium ion and the sulfonium ion may be mixed with the perovskite compound, or the perovskite compound and the at least one selected from the group consisting of the phosphonium ion and the sulfonium ion may be mixed such that the entire mixture is uniform. Such a photoelectric conversion layer can be formed, for example, by the forming of the photoelectric conversion layer in the manufacturing method according to the first embodiment, i.e., by using the precursor solution of the perovskite compound and the solution mixture containing the at least one selected from the group consisting of the phosphonium salt and the sulfonium salt. One possible reason why the photoelectric conversion efficiency is improved by such a photoelectric conversion layer is that, by forming the photoelectric conversion layer using the solution mixture containing the at least one selected from the group consisting of the phosphonium salt and the sulfonium salt, particle diameters of crystals of the perovskite compound in the photoelectric conversion layer are increased and carrier recombination is reduced. Also from the fact that the photoelectric conversion layer formed from the solution mixture containing the at least one selected from the group consisting of the phosphonium salt and the sulfonium salt extends a PL lifetime, it is thought that a carrier diffusion length is increased because the at least one selected from the group consisting of the phosphonium ion and the sulfonium ion is included.

In the photoelectric conversion element of the first embodiment, the perovskite compound included in the photoelectric conversion layer may have an average primary particle diameter of, for example, 1 μm or more. The primary particle of the perovskite compound included in the photoelectric conversion layer is, for example, formed of a polycrystal.

When the perovskite compound has an average primary particle diameter of 1 μm or more, carrier recombination is further reduced. Hence, the photoelectric conversion element of the first embodiment has further improved photoelectric conversion efficiency. The average primary particle diameter of the perovskite compound in the photoelectric conversion layer of the photoelectric conversion element of the first embodiment is determined by measuring the primary particle diameters of the particles of the perovskite compound using a SEM image and averaging the measured values. Each primary particle diameter measured thereby is an average of the maximum diameter and the minimum diameter of each primary particle. For example, from the particles in a SEM image, 50 particles are selected in order of descending primary particle diameter. The primary particle diameters of the 50 particles are averaged, and the resulting value is employed as the average primary particle diameter. The average primary particle diameter of the perovskite compound is, for example, 100 μm or less.

Hereinafter, the at least one selected from the group consisting of the phosphonium ion and the sulfonium ion included in the photoelectric conversion layer of the photoelectric conversion element of the first embodiment is referred to as “the phosphonium ion and/or the sulfonium ion”.

In the photoelectric conversion layer of the photoelectric conversion element of the first embodiment, the phosphonium ion and/or the sulfonium ion may be present between the crystals of the perovskite compound. It is thought that since the phosphonium ion and/or the sulfonium ion are present in such a state in the photoelectric conversion layer, a carrier path is formed between the crystals of the perovskite compound and consequently carrier recombination is further reduced. Therefore, the photoelectric conversion element of the first embodiment configured as above can further improve the photoelectric conversion efficiency.

Energy of a PL peak of the photoelectric conversion layer of the photoelectric conversion element of the first embodiment may be substantially equal to energy of a PL peak of the perovskite compound included in the photoelectric conversion layer. That is, a band gap of the photoelectric conversion layer of the photoelectric conversion element of the first embodiment may be substantially equal to a band gap of the perovskite compound included in the photoelectric conversion layer. In other words, in the photoelectric conversion layer of the photoelectric conversion element of the first embodiment, the crystal structure of the perovskite compound remains unchanged regardless of the presence or absence of the phosphonium ion and/or the sulfonium ion, and the crystal structure of a perovskite compound including neither phosphonium ion nor sulfonium ion can be maintained therein. Hence, because of this configuration, the photoelectric conversion layer of the photoelectric conversion element of the first embodiment can further improve the photoelectric conversion efficiency without changing its light absorption properties (e.g., the wavelength of light it absorbs). Saying that the energies of the PL peaks are substantially equal to each other means that a difference of the energies of the PL peaks is 0 eV or more and 0.03 eV or less. Additionally, saying that the band gaps are substantially equal to each other means that a difference of the band gaps is 0 eV or more and 0.03 eV or less.

The energy of the PL peak of the photoelectric conversion layer of the photoelectric conversion element of the first embodiment may be, for example, less than 1.55 eV. That is, the wavelength of the PL peak of the photoelectric conversion layer of the photoelectric conversion element of the first embodiment may be more than 800 nm. Owing to such a PL peak, the photoelectric conversion element of the first embodiment can further improve the photoelectric conversion efficiency. The energy of the PL peak of the photoelectric conversion layer of the photoelectric conversion element of the first embodiment may be, for example, 1.1 eV or more. That is, the wavelength of the PL peak of the photoelectric conversion material according to the first embodiment may be 1127 nm or less.

In the photoelectric conversion element of the first embodiment, for example, the above phosphonium ion is a cation forming a portion of the phosphonium salt, and the above sulfonium ion is a cation forming a portion of the sulfonium salt. To improve the photoelectric conversion efficiency of the photoelectric conversion element, the phosphonium salt and/or the sulfonium salt may include at least one selected from the group consisting of an alkyl group and an aryl group. The number of carbon atoms in the alkyl group may be 1 or more and 10 or less. The number of carbon atoms in the alkyl group may be 1 or more and 7 or less.

To improve the photoelectric conversion efficiency of the photoelectric conversion element, the phosphonium salt and/or the sulfonium salt may include an alkyl group, and the number of carbon atoms in the alkyl group may be 1 or more and 10 or less. The number of carbon atoms in the alkyl group may be 1 or more and 7 or less.

To improve the photoelectric conversion efficiency of the photoelectric conversion material, the phosphonium salt may include a quaternary phosphonium salt. The phosphonium salt may include a quaternary phosphonium salt and a phosphonium salt other than a quaternary phosphonium salt. To further improve the photoelectric conversion efficiency of the photoelectric conversion element, the phosphonium salt may be a quaternary phosphonium salt.

To improve the photoelectric conversion efficiency of the photoelectric conversion element, the sulfonium salt may include a tertiary sulfonium salt. The sulfonium salt may include a tertiary sulfonium salt and a sulfonium salt other than a tertiary sulfonium salt. To further improve the photoelectric conversion efficiency of the photoelectric conversion material, the sulfonium salt may be a tertiary sulfonium salt.

To improve the photoelectric conversion efficiency of the photoelectric conversion element, the phosphonium salt and/or the sulfonium salt may include a halogen element. The halogen element is, for example, fluorine, chlorine, bromine, or iodine.

To improve the photoelectric conversion efficiency of the photoelectric conversion element, the phosphonium salt and/or the sulfonium salt may include iodine as the above halogen element.

To improve the photoelectric conversion efficiency of the photoelectric conversion element, the phosphonium salt may include an iodine-containing phosphonium salt. The iodine-containing phosphonium salt may include at least one selected from the group consisting of tributylmethylphosphonium iodide, methyltriphenylphosphonium iodide, ethyltriphenylphosphonium iodide, and isopropyltriphenylphosphonium iodide.

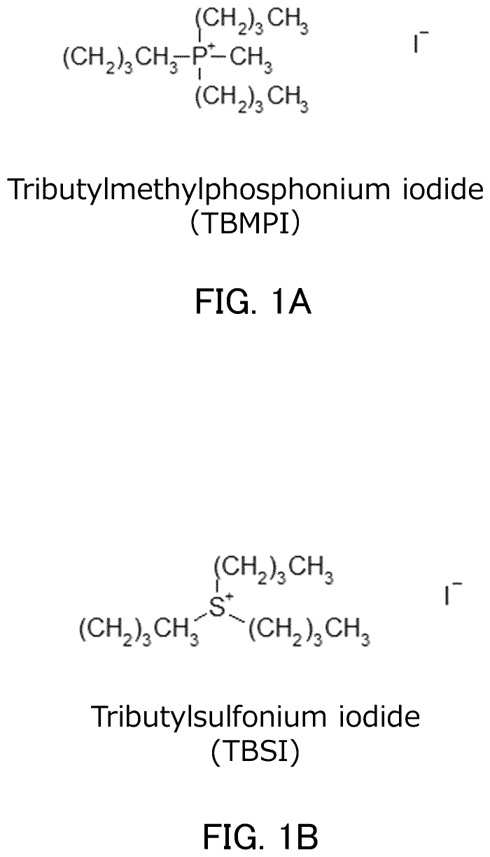

When an iodine-containing quaternary phosphonium salt is used as the iodine-containing phosphonium salt, the iodine-containing phosphonium salt may be at least one selected from the group consisting of tributylmethylphosphonium iodide, methyltriphenylphosphonium iodide, ethyltriphenylphosphonium iodide, and isopropyltriphenylphosphonium iodide to further improve the photoelectric conversion efficiency of the photoelectric conversion element. FIG. 1A shows a molecular structure of tributylmethylphosphonium iodide being an example of the quaternary phosphonium salt that can be used as the phosphonium salt in the photoelectric conversion element of the first embodiment. Hereinafter, tributylmethylphosphonium iodide is referred to as “TBMPI”.

To improve the photoelectric conversion efficiency of the photoelectric conversion element, the sulfonium salt may include an iodine-containing sulfonium salt. The iodine-containing sulfonium salt may include at least one selected from the group consisting of tributylsulfonium iodide and trimethylsulfonium iodide.

When an iodine-containing tertiary sulfonium salt is used as the iodine-containing sulfonium salt, to further improve the photoelectric conversion efficiency of the photoelectric conversion element, the iodine-containing sulfonium salt may be at least one selected from the group consisting of tributylsulfonium iodide and trimethylsulfonium iodide. FIG. 1B shows a molecular structure of tributylsulfonium iodide being an example of the tertiary sulfonium salt that can be used as the sulfonium salt in the photoelectric conversion element of the first embodiment. Hereinafter, tributylsulfonium iodide is referred to as “TBSI”.

To further improve the photoelectric conversion efficiency of the photoelectric conversion element, a molar ratio of the phosphonium salt or the sulfonium salt to the perovskite compound may be 0.01 or more and 0.50 or less in the photoelectric conversion layer of the photoelectric conversion element of the first embodiment.

To further improve the photoelectric conversion efficiency of the photoelectric conversion element, the molar ratio of the phosphonium salt or the sulfonium salt to the perovskite compound may be 0.01 or more and 0.20 or less.

To further improve the photoelectric conversion efficiency of the photoelectric conversion element, the molar ratio of the phosphonium salt or the sulfonium salt to the perovskite compound may be 0.05 or more and 0.10 or less.

The molar ratio of the phosphonium salt or the sulfonium salt to the perovskite compound may be any pair of numerical values selected from 0.01, 0.05, 0.07, 0.1, 0.15, 0.2, and 0.5.

The perovskite compound has a high light absorption coefficient in a wavelength region of a solar spectrum and has high carrier mobility. Hence, the photoelectric conversion element including the photoelectric conversion layer including the perovskite compound has high photoelectric conversion efficiency.

The perovskite compound may include a halogen anion. That is, the perovskite compound may be a halide.

The perovskite compound may be formed of a monovalent cation, a divalent cation, and a halogen anion. In this case, the divalent cation may include at least one selected from the group consisting of a Sn cation, a Ge cation, and a Pb cation.

The monovalent cation of the perovskite compound may include 50 mol % or more of an inorganic cation.

The perovskite compound is represented, for example, by a composition formula ABX₃. In this formula, A is a monovalent cation, B is a divalent metal cation, and X is a monovalent anion.

The monovalent cation A is, for example, an organic cation or an alkali metal cation. As described above, the monovalent cation A may include 50 mol % or more of an inorganic cation, namely, an alkali metal cation.

Examples of the organic cation include a methylammonium cation (CH₃NH₃⁺), a formamidinium cation (NH₂CHNH₂⁺), and a guanidinium ion (C(NH₂)₃⁺).

Examples of the alkali metal cation include a Cs cation and a Rb cation.

The symbol B is a divalent metal cation. The divalent cation B is, for example, a Pb cation, a Sn cation, or a Ge cation.

The symbol X is a monovalent anion. The anion X is, for example, a halogen anion. The halogen anion is, for example, chlorine, bromine, or iodine.

Different sites of the cation A may include different ions, and so may different sites of the cation B and different sites of the anion X.

The perovskite compound may be at least one selected from the group consisting of CsSnI₃, CsGeI₃, and CsPbI₃.

The photoelectric conversion layer of the photoelectric conversion element of the first embodiment may further include SnF₂. When the perovskite compound includes a Sn cation as the divalent cation, the further included SnF₂ can reduce Sn defects. Hence, when the photoelectric conversion layer of the photoelectric conversion element of the first embodiment further includes SnF₂, the photoelectric conversion efficiency can be improved.

Hereinafter, the configuration of the photoelectric conversion element of the first embodiment will be described in more details.

As described above, the photoelectric conversion element according to the first embodiment includes the first electrode, the photoelectric conversion layer, and the second electrode. The photoelectric conversion element according to the first embodiment may include the first electrode, the photoelectric conversion layer, and the second electrode in this order.

The photoelectric conversion element according to the first embodiment is, for example, a solar cell. Herein, a light source for a solar cell is not limited to sunlight, and may be indoor illumination.

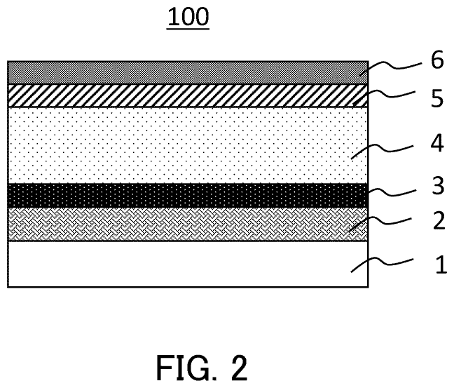

FIG. 2 is a cross-sectional view schematically showing the configuration of a photoelectric conversion element 100 being an example of the first embodiment.

The photoelectric conversion element 100 includes a substrate 1, a first electrode 2, an electron transport layer 3, a photoelectric conversion layer 4, a hole transport layer 5, and a second electrode 6 in this order. The substrate 1, the electron transport layer 3, and the hole transport layer 5 may be omitted.

The photoelectric conversion layer 4 may be a single layer, or may be composed of a plurality of layers. When the photoelectric conversion layer 4 is a single layer, the photoelectric conversion layer 4 is the above photoelectric conversion layer. When the photoelectric conversion layer 4 is composed of a plurality of layers, at least one of the layers is the above photoelectric conversion layer.

Upon irradiation of the photoelectric conversion element 100 with light, the photoelectric conversion layer 4 absorbs the light and then charge separation into electrons and holes occurs. The electrons resulting from this charge separation transfer to the first electrode 2 through the electron transport layer 3. On the other hand, the holes formed in the photoelectric conversion layer 4 transfer to the second electrode 6 via the hole transport layer 5. The photoelectric conversion element 100 can thereby draw out an electric current from the first electrode 2 as a negative electrode and the second electrode 6 as a positive electrode.

The components of the photoelectric conversion element 100 will be specifically described hereinafter.

### (Substrate 1)

The substrate 1 supports the layers in the photoelectric conversion element 100. The substrate 1 can be formed using a transparent material. A glass substrate or a plastic substrate, for example, can be used as the substrate 1. The plastic substrate may be, for example, a plastic film.

When the second electrode 6 has a light-transmitting property, the substrate 1 may be formed of a material not having a light-transmitting property. As the material can be used a metal, a ceramic, or a resin material having a low light-transmitting property.

When the first electrode 2 is strong enough to support the layers, the substrate 1 may be omitted.

### (First Electrode 2)

The first electrode 2 has electrical conductivity.

The first electrode 2 has a light-transmitting property. For example, the first electrode 2 allows visible to near-infrared light to pass therethrough.

The first electrode 2 is formed of, for example, a material being transparent and having electrical conductivity. The material is, for example, a metal oxide or a metal nitride. The material is, for example,
(i) titanium oxide doped with at least one selected from the group consisting of lithium, magnesium, niobium, and fluorine,
(ii) gallium oxide doped with at least one selected from the group consisting of tin and silicon,
(iii) gallium nitride doped with at least one selected from the group consisting of silicon and oxygen,
(iv) tin oxide doped with at least one selected from the group consisting of antimony and fluorine,
(v) zinc oxide doped with at least one selected from the group consisting of boron, aluminum, gallium, and indium,
(vi) indium-tin composite oxide, or
(vii) a composite thereof.

The first electrode 2 may be formed to have a pattern that allows light to pass therethrough. The pattern that allows light to pass therethrough is, for example, a linear pattern, a wave line pattern, a lattice pattern, or a perforated-metal-like pattern where a lot of small through holes are regularly or irregularly arranged. When the first electrode 2 has any of these patterns, light can pass through portions without the electrode material. Thus, a non-transparent material can be used for the first electrode 2 having the pattern that allows light to pass therethrough. Examples of the non-transparent electrode material include platinum, gold, silver, copper, aluminum, rhodium, indium, titanium, iron, nickel, tin, zinc, or an alloy including any of these. An electrically conductive carbon material may be used as the non-transparent electrode material.

The light-transmitting property of the first electrode 2 is not necessarily achieved by the above-described pattern that allows light to pass therethrough. For example, the first electrode 2 may be formed as a thin metal film having a thickness of approximately 10 nm. The thin metal film is formed of, for example, platinum, gold, silver, copper, aluminum, rhodium, indium, titanium, iron, nickel, tin, zinc, or an alloy including any of these. An electrically conductive carbon material may be used instead of these metal materials.

In the case where the photoelectric conversion element 100 does not include the electron transport layer 3, the first electrode 2 has a property of blocking holes from the photoelectric conversion layer 4. In this case, the first electrode 2 is not in ohmic contact with the photoelectric conversion layer 4. The property of blocking holes from the photoelectric conversion layer 4 is a property of allowing only electrons formed in the photoelectric conversion layer 4 to pass and not allowing holes to pass. The Fermi energy of a material having such a property is higher than the energy of the photoelectric conversion layer 4 at an upper part of the valence band. The Fermi energy of a material having such a property may be higher than the Fermi energy of the photoelectric conversion layer 4. The material is specifically, for example, aluminum.

In the case where the photoelectric conversion element 100 includes the electron transport layer 3, the first electrode 2 does not necessarily have the property of blocking holes from the photoelectric conversion layer 4. In this case, the first electrode 2 can be formed of a material capable of forming an ohmic contact with the photoelectric conversion layer 4. In this case, the first electrode 2 may be in ohmic contact with the photoelectric conversion layer 4, or is not necessarily in ohmic contact with the photoelectric conversion layer 4.

The transmittance of the first electrode 2 may be, for example, 50% or more, or 80% or more. The wavelength of light that is to pass through the first electrode 2 depends on the absorption wavelength of the photoelectric conversion layer 4.

The thickness of the first electrode 2 may be, for example, 1 nm or more and 1000 nm or less.

### (Electron Transport Layer 3)

The electron transport layer 3 includes an electron transport material. The electron transport material can be a semiconductor. The electron transport layer 3 may be formed of a semiconductor having a band gap of 3.0 eV or more. In this case, visible light and infrared light are allowed to pass therethrough to the photoelectric conversion layer 4.

Examples of the electron transport material include inorganic n-type semiconductors.

Examples of the inorganic n-type semiconductor include a metal oxide, a metal nitride, and a perovskite oxide. The metal oxide is, for example, an oxide of Cd, Zn, In, Pb, Mo, W, Sb, Bi, Cu, Hg, Ti, Ag, Mn, Fe, V, Sn, Zr, Sr, Ga, Si, or Cr. The metal oxide is, for example, TiO₂ or SnO₂. The metal nitride is, for example, GaN. The perovskite oxide is, for example, SrTiO₃ or CaTiO₃.

A semiconductor having a band gap of 6.0 eV or more may be used as the electron transport layer 3 to effectively allow ultraviolet to pass therethrough to the photoelectric conversion layer 4. Examples of the semiconductor include halides, such as lithium fluoride and calcium fluoride, of alkali metals and alkaline earth metals, alkali metal oxides, such as magnesium oxide, and silicon dioxide. In this case, the electron transport layer 3 may have a thickness of, for example, 10 nm or less to secure the electron transport capability of the electron transport layer 3.

The electron transport layer 3 may include a plurality of layers formed of different materials.

### (Photoelectric Conversion Layer 4)

As described above, the photoelectric conversion layer 4 corresponds to the photoelectric conversion layer of the photoelectric conversion element of the first embodiment. That is, the photoelectric conversion layer 4 includes: the perovskite compound; and the phosphonium ion and/or the sulfonium ion. In the photoelectric conversion layer 4, the phosphonium ion and/or the sulfonium ion may be mixed with the perovskite compound, and the perovskite compound and the phosphonium ion and/or the sulfonium ion may be mixed such that the entire mixture is uniform. The composition of the photoelectric conversion layer 4 may be uniform in the thickness direction and, even more, the composition of the entire photoelectric conversion layer 4 may be uniform.

The photoelectric conversion layer 4 is required to include the perovskite compound and the phosphonium ion and/or the sulfonium ion, and may include a defect or impurities.

The photoelectric conversion layer 4 may further include a component different from the perovskite compound, the phosphonium ion, and the sulfonium ion.

The photoelectric conversion layer 4 has a thickness of, for example, 50 nm or more and 10 μm or less.

The photoelectric conversion layer 4 can be formed by a coating technique involving a solution, a printing technique, or a deposition technique. Examples of the coating technique include doctor blade coating, bar coating, spraying, dip coating, inkjet coating, slit coating (namely, die coating), and spin coating.

### (Hole Transport Layer 5)

The hole transport layer 5 includes a hole transport material. The hole transport material is a material that transports holes. The hole transport material is, for example, an organic semiconductor or an inorganic semiconductor.

Examples of the organic semiconductor include triphenylamine, triallylamine, phenylbenzidine, phenylenevinylene, tetrathiafulvalene, vinylnaphthalene, vinylcarbazole, thiophene, aniline, pyrrole, carbazole, triptycene, fluorene, azulene, pyrene, pentacene, perylene, acridine, and phthalocyanine.

Typical examples of the organic semiconductor used as the hole transport material include 2,2′,7,7′-tetrakis-(N,N-di-p-methoxyphenylamine) 9,9′-spirobifluorene, poly [bis(4-phenyl) (2,4,6-trimethylphenyl)amine] (which may be referred to as “PTAA” hereinafter), poly(3-hexylthiophene-2,5-diyl), poly(3,4-ethylenedioxythiophene), and copper phthalocyanine.

The inorganic semiconductor used as the hole transport material is a p-type semiconductor. Examples of the inorganic semiconductor include Cu₂O, CuGaO₂, CuSCN, CuI, NiOₓ, MoOₓ, V₂O₅, and carbon materials such as graphene oxide. The symbol x satisfies x>0.

The hole transport layer 5 may include a plurality of layers formed of different materials. For example, hole transport properties of the hole transport layer 5 are improved by stacking the plurality of layers whose ionization potentials are smaller than that of the photoelectric conversion layer 4 such that the ionization potentials decrease layer by layer.

The thickness of the hole transport layer 5 may be 1 nm or more and 1000 nm or less, or 10 nm or more and 50 nm or less. This allows the hole transport layer 5 to exhibit sufficiently high hole transport properties. Consequently, the resistance of the photoelectric conversion element 100 can be maintained at a low level, and high photoelectric conversion efficiency can be achieved.

The hole transport layer 5 is formed, for example, by a coating technique, a printing technique, or a deposition technique. The same can be said to the photoelectric conversion layer 4. Examples of the coating technique include doctor blade coating, bar coating, spraying, dip coating, inkjet coating, slit coating (namely, die coating), and spin coating. Examples of the printing technique include screen printing. If needed, the hole transport layer 5 may be formed using a mixture of a plurality of materials and then compressed or baked. In the case where the material of the hole transport layer 5 is a low-molecular-weight organic substance or an inorganic semiconductor, the hole transport layer 5 can be produced by vacuum deposition.

The hole transport layer 5 may include not only the hole transport material but an additive to increase the electrical conductivity. Examples of the additive include a supporting electrolyte, a solvent, and a dopant. The supporting electrolyte and the solvent stabilize holes in the hole transport layer 5. The dopant increases the number of holes in the hole transport layer 5.

Examples of the supporting electrolyte include an ammonium salt, an alkali metal salt, an alkaline earth metal salt, and a transition metal salt. Examples of the ammonium salt include tetrabutylammonium perchlorate, tetraethylammonium hexafluorophosphate, an imidazolium salt, and a pyridinium salt. Examples of the alkali metal salt include lithium bis(trifluoromethanesulfonyl)imide (LiTFSI), lithium perchlorate, and potassium tetrafluoroborate. Examples of the alkaline earth metal salt include lithium bis(trifluoromethanesulfonyl)imide and calcium (II) bis(trifluoromethanesulfonyl)imide. Examples of the transition metal salt include zinc (II) bis(trifluoromethanesulfonyl)imide and tris [4-tert-butyl-2-(1H-pyrazole-1-yl)pyridine] cobalt (III) tris(trifluoromethanesulfonyl)imide.

Examples of the dopant include a fluorine-containing aromatic boron compound. Examples of the fluorine-containing aromatic boron compound include tris(pentafluorophenyl) borane.

The solvent included in the hole transport layer 5 may have excellent ion conductivity. The solvent may be an aqueous solvent or an organic solvent. To make the solute more stable, the solvent included in the hole transport layer 5 may be an organic solvent. Examples of the organic solvent include heterocyclic compound solvents, such as tert-butylpyridine (tBP), pyridine, and n-methylpyrrolidone.

For example, PTAA may be used as the hole transport material, and LiTFSI and tBP may be used as the additive.

An ionic liquid may be used as the solvent. The ionic liquid may be used alone, or may be used after mixed with a different solvent. The ionic liquid is desirable for its low volatility and high flame retardancy.

Examples of the ionic liquid include imidazolium ionic liquids such as 1-ethyl-3-methylimidazolium tetracyano borate, pyridine ionic liquids, alicyclic amine ionic liquids, aliphatic amine ionic liquids, and azonium amine ionic liquids.

### (Second Electrode 6)

The second electrode 6 has electrical conductivity.

In the case where the photoelectric conversion element 100 does not include the hole transport layer 5, the second electrode 6 has a property of blocking electrons from the photoelectric conversion layer 4. In this case, the second electrode 6 is not in ohmic contact with the photoelectric conversion layer 4. The property of blocking electrons from the photoelectric conversion layer 4 refers to a property of allowing only holes formed in the photoelectric conversion layer 4 to pass and not allowing electrons to pass. The Fermi energy of a material having such a property is lower than the energy of the photoelectric conversion layer 4 at a lower part of the conduction band. The Fermi energy of a material having such a property may be lower than the Fermi energy of the photoelectric conversion layer 4. The material is specifically platinum, gold, or a carbon material such as graphene.

In the case where the photoelectric conversion element 100 includes the hole transport layer 5, the second electrode 6 does not necessarily have the property of blocking electrons from the photoelectric conversion layer 4. In this case, the second electrode 6 can be formed of a material capable of forming an ohmic contact with the photoelectric conversion layer 4. Therefore, the second electrode 6 can be formed to have a light-transmitting property.

An electrode that is the first electrode 2 or the second electrode 6 and that is configured to allow light to be incident thereon needs to have a light-transmitting property. That is, one of the first electrode 2 and the second electrode 6 does not necessarily have a light-transmitting property. That is, one of the first electrode 2 and the second electrode 6 does not necessarily include a material having a light-transmitting property, or does not necessarily have a pattern including an opening portion that allows light to pass therethrough.

### (Porous Layer)

A porous layer is formed on the electron transport layer 3, for example, by a coating technique. In the case where the photoelectric conversion element 100 does not include the electron transport layer 3, the porous layer is formed on the first electrode 2.

A pore structure provided by the porous layer serves as a foundation at the time of formation of the photoelectric conversion layer 4. The porous layer does not prevent light absorption by the photoelectric conversion layer 4 and electron transfer from the photoelectric conversion layer 4 to the electron transport layer 3.

The porous layer includes a porous body.

The porous body is formed of, for example, continuous insulating particles or continuous semiconductor particles. The insulating particles are, for example, aluminum oxide particles or silicon oxide particles. The semiconductor particles are, for example, inorganic semiconductor particles. The inorganic semiconductor is, for example, a metal oxide, a perovskite oxide of a metal element, a sulfide of a metal element, or a metal chalcogenide. The metal oxide is, for example, an oxide of Cd, Zn, In, Pb, Mo, W, Sb, Bi, Cu, Hg, Ti, Ag, Mn, Fe, V, Sn, Zr, Sr, Ga, Si, or Cr. The metal oxide is, for example, TiO₂. The perovskite oxide of a metal element is, for example, SrTiO₃ or CaTiO₃. The sulfide of a metal element is, for example, CdS, ZnS, In₂S₃, PbS, Mo₂S, WS₂, Sb₂S₃, Bi₂S₃, ZnCdS₂, or Cu₂S. The metal chalcogenide is, for example, CsSe, In₂Se₃, WSe₂, HgS, PbSe, or CdTe.

The thickness of the porous layer may be 0.01 μm or more and 10 μm or less, or 0.05 μm or more and 1 μm or less.

Regarding surface roughness of the porous layer, a surface roughness factor determined by “effective area/projected area” may be 10 or greater, or 100 or greater. The projected area refers to the area of a shadow behind an object irradiated with light from the front. The effective area refers to the actual surface area of an object. The effective area can be calculated from a volume of an object, the specific surface area of the material of the object, and the bulk density of the material of the object, the volume being determined from the projected area and the thickness of the object. The specific surface area is measured, for example, by a nitrogen adsorption method.

A void in the porous layer is continuous from one principal surface of the porous layer to the other principal surface. That is, a void in the porous layer is continuous from a principal surface of the porous layer in contact with the photoelectric conversion layer 4 to a principal surface of the porous layer in contact with the electron transport layer 3. This allows the material of the photoelectric conversion layer 4 to fill the void of the porous layer and reach the surface of the electron transport layer 3. The photoelectric conversion layer 4 and the electron transport layer 3 are thus in direct contact to each other and therefore can give and receive electrons therebetween.

Inclusion of the porous layer makes it easy to form the photoelectric conversion layer 4. When the porous layer is included, the material of the photoelectric conversion layer 4 enters the void of the porous layer and the porous layer serves as a foothold for the photoelectric conversion layer 4. This makes it unlikely that the material of the photoelectric conversion layer 4 is repelled by the surface of the porous layer or aggregates on the surface of the porous layer. Consequently, the photoelectric conversion layer 4 can be easily formed as a uniform film. The photoelectric conversion layer 4 can be formed by the above coating technique or the like.

The porous layer can increase the optical path length of light passing through the photoelectric conversion layer 4 by causing light scattering. The amount of electrons and holes formed in the photoelectric conversion layer 4 is expected to increase with the increase of the optical path length.

### Second Embodiment

A first example of a photoelectric conversion material of a second embodiment includes a perovskite compound and a phosphonium ion.

A second example of the photoelectric conversion material of the second embodiment includes a perovskite compound and a sulfonium ion.

A third example of the photoelectric conversion material of the second embodiment includes a perovskite compound, a phosphonium ion, and a sulfonium ion.

Hereinafter, the first to third examples of the photoelectric conversion material of the second embodiment are collectively called the photoelectric conversion material of the second embodiment. That is, the photoelectric conversion material of the second embodiment is a photoelectric conversion material including: a perovskite compound; and at least one selected from the group consisting of a phosphonium ion and a sulfonium ion.

The photoelectric conversion material of the second embodiment configured as above can improve the photoelectric conversion efficiency.

The photoelectric conversion material of the second embodiment may be, for example, a material mixture obtained by mixing the at least one selected from the group consisting of the phosphonium ion and the sulfonium ion with the perovskite compound. In the photoelectric conversion material of the second embodiment, the perovskite compound and the at least one selected from the group consisting of the phosphonium ion and the sulfonium ion may be mixed such that the entire mixture is uniform. The photoelectric conversion material of the second embodiment configured as above can further improve the photoelectric conversion efficiency. One possible reason why the photoelectric conversion efficiency is improved is that, since the at least one selected from the group consisting of the phosphonium ion and the sulfonium ion is included, the particle diameters of the crystals of the perovskite compound in the photoelectric conversion material are increased and carrier recombination is reduced. Also from the fact that the PL lifetime is extended when the at least one selected from the group consisting of the phosphonium ion and the sulfonium ion is included, it is thought that a carrier diffusion length is increased because the at least one selected from the group consisting of the phosphonium ion and the sulfonium ion is included.

In the photoelectric conversion material of the second embodiment, the above perovskite compound may have an average primary particle diameter of, for example, 1 μm or more. The primary particle of the perovskite compound included in the photoelectric conversion material is, for example, formed of a polycrystal. When the perovskite compound has an average primary particle diameter of 1 μm or more, carrier recombination is further reduced. Hence, the photoelectric conversion material of the second embodiment has further improved photoelectric conversion efficiency. The average primary particle diameter of the perovskite compound in the photoelectric conversion material of the second embodiment is determined by measuring the primary particle diameters of the particles of the perovskite compound using a SEM image and averaging the measured values. Each primary particle diameter measured thereby is an average of the maximum diameter and the minimum diameter of each primary particle. For example, from the particles in a SEM image, 50 particles are selected in order of descending primary particle diameter. The primary particle diameters of the 50 particles are averaged, and the resulting value is employed as the average primary particle diameter. The average primary particle diameter of the perovskite compound is, for example, 100 μm or less.

Hereinafter, the at least one included in the photoelectric conversion material of the second embodiment and selected from the group consisting of the phosphonium ion and the sulfonium ion is referred to as “the phosphonium ion and/or the sulfonium ion”.

In the photoelectric conversion material of the second embodiment, the phosphonium ion and/or the sulfonium ion may be present between the crystals of the perovskite compound. It is thought that since the phosphonium ion and/or the sulfonium ion are present in such a state in the photoelectric conversion material, a carrier path is formed between the crystals of the perovskite compound and consequently carrier recombination is further reduced. Therefore, the photoelectric conversion material of the second embodiment configured as above can further improve the photoelectric conversion efficiency.

Energy of a PL peak of the photoelectric conversion material of the second embodiment may be substantially equal to energy of a PL peak of the perovskite compound included in the photoelectric conversion material. That is, a band gap of the photoelectric conversion material of the second embodiment may be substantially equal to a band gap of the perovskite compound included in the photoelectric conversion material. In other words, in the photoelectric conversion material of the second embodiment, the crystal structure remains unchanged regardless of the presence or absence of the phosphonium ion and/or the sulfonium ion, and the crystal structure of a perovskite compound including neither phosphonium ion nor sulfonium ion can be maintained therein. Hence, because of this configuration, the photoelectric conversion material of the second embodiment can further improve the photoelectric conversion efficiency without changing its light absorption properties (e.g., the wavelength of light it absorbs). Saying that the energies of the PL peaks are substantially equal to each other means that a difference of the energies of the PL peaks is 0 eV or more and 0.03 eV or less. Additionally, saying that the band gaps are substantially equal to each other means that a difference of the band gaps is 0 eV or more and 0.03 eV or less.

The energy of the PL peak of the photoelectric conversion material of the second embodiment may be, for example, less than 1.55 eV. That is, the wavelength of the PL peak of the photoelectric conversion material of the second embodiment may be more than 800 nm. The photoelectric conversion material of the second embodiment having such a PL peak can further improve the photoelectric conversion efficiency. The energy of the PL peak of the photoelectric conversion material of the second embodiment may be, for example, 1.1 eV or more. That is, the wavelength of the PL peak of the photoelectric conversion material according to the second embodiment may be 1127 nm or less.

In the photoelectric conversion material of the second embodiment, for example, the above phosphonium ion is a cation forming a portion of a phosphonium salt, and the above sulfonium ion is a cation forming a portion of a sulfonium salt. To improve the photoelectric conversion efficiency of the photoelectric conversion material, the phosphonium salt and/or the sulfonium salt may include at least one selected from the group consisting of an alkyl group and an aryl group. The number of carbon atoms in the alkyl group may be 1 or more and 10 or less. The number of carbon atoms in the alkyl group may be 1 or more and 7 or less.

To improve the photoelectric conversion efficiency of the photoelectric conversion material, the phosphonium salt and/or the sulfonium salt may include an alkyl group, and the number of carbon atoms in the alkyl group may be 1 or more and 10 or less. The number of carbon atoms in the alkyl group may be 1 or more and 7 or less.

To improve the photoelectric conversion efficiency of the photoelectric conversion material, the phosphonium salt may include a quaternary phosphonium salt. The phosphonium salt may include a quaternary phosphonium salt and a phosphonium salt other than a quaternary phosphonium salt. To further improve the photoelectric conversion efficiency of the photoelectric conversion material, the phosphonium salt may be a quaternary phosphonium salt.

To improve the photoelectric conversion efficiency of the photoelectric conversion material, the sulfonium salt may include a tertiary sulfonium salt.

The sulfonium salt may include a tertiary sulfonium salt and a sulfonium salt other than a tertiary sulfonium salt. To further improve the photoelectric conversion efficiency of the photoelectric conversion material, the sulfonium salt may be a tertiary sulfonium salt.

To improve the photoelectric conversion efficiency of the photoelectric conversion material, the phosphonium salt and/or the sulfonium salt may include a halogen element. The halogen element is, for example, fluorine, chlorine, bromine, or iodine.

To improve the photoelectric conversion efficiency of the photoelectric conversion material, the phosphonium salt and/or the sulfonium salt may include iodine as the above halogen element.

To improve the photoelectric conversion efficiency of the photoelectric conversion material, the phosphonium salt may include an iodine-containing phosphonium salt. The iodine-containing phosphonium salt may include at least one selected from the group consisting of TBMPI, methyltriphenylphosphonium iodide, ethyltriphenylphosphonium iodide, and isopropyltriphenylphosphonium iodide.

When an iodine-containing quaternary phosphonium salt is used as the iodine-containing phosphonium salt, to further improve the photoelectric conversion efficiency of the photoelectric conversion material, the iodine-containing phosphonium salt may be at least one selected from the group consisting of TBMPI, methyltriphenylphosphonium iodide, ethyltriphenylphosphonium iodide, and isopropyltriphenylphosphonium iodide. The molecular structure of TBMPI is as shown in FIG. 1A.

To improve the photoelectric conversion efficiency of the photoelectric conversion material, the sulfonium salt may include an iodine-containing sulfonium salt. The iodine-containing sulfonium salt may include at least one selected from the group consisting of tributylsulfonium iodide and trimethylsulfonium iodide.

When an iodine-containing tertiary sulfonium salt is used as the iodine-containing sulfonium salt, to further improve the photoelectric conversion efficiency of the photoelectric conversion material, the iodine-containing sulfonium salt may be at least one selected from the group consisting of TBSI and trimethylsulfonium iodide. The molecular structure of TBSI is as shown in FIG. 1B.

To further improve the photoelectric conversion efficiency of the photoelectric conversion material, a molar ratio of the phosphonium salt or the sulfonium salt to the perovskite compound may be 0.01 or more and 0.50 or less in the photoelectric conversion material of the second embodiment.

To further improve the photoelectric conversion efficiency of the photoelectric conversion material, the molar ratio of the phosphonium salt or the sulfonium salt to the perovskite compound may be 0.01 or more and 0.20 or less.

To further improve the photoelectric conversion efficiency of the photoelectric conversion material, the molar ratio of the phosphonium salt or the sulfonium salt to the perovskite compound may be 0.05 or more and 0.10 or less.

The molar ratio of the phosphonium salt or the sulfonium salt to the perovskite compound may be any pair of numerical values selected from 0.01, 0.05, 0.07, 0.1, 0.15, 0.2, and 0.5.

The perovskite compound has a high light absorption coefficient in a wavelength region of a solar spectrum and has high carrier mobility. Hence, the photoelectric conversion material including the perovskite compound has high photoelectric conversion efficiency.

The perovskite compound may include a halogen anion. That is, the perovskite compound may be a halide.

The perovskite compound may be formed of a monovalent cation, a divalent cation, and a halogen anion. In this case, the divalent cation may include at least one selected from the group consisting of a Sn cation, a Ge cation, and a Pb cation.

The monovalent cation of the perovskite compound may include 50 mol % or more of an inorganic cation.

The perovskite compound is represented, for example, by a composition formula ABX₃. In this formula, A is a monovalent cation, B is a divalent metal cation, and X is a monovalent anion.

The monovalent cation A is, for example, an organic cation or an alkali metal cation. As described above, the monovalent cation A may include 50 mol % or more of an inorganic cation, namely, an alkali metal cation.

Examples of the organic cation include a methylammonium cation (CH₃NH₃⁺), a formamidinium cation (NH₂CHNH₂⁺), and a guanidinium ion (C(NH₂)₃⁺).

Examples of the alkali metal cation include a Cs cation and a Rb cation.

The symbol B is a divalent metal cation. The divalent cation B is, for example, a Pb cation, a Sn cation, or a Ge cation.

The symbol X is a monovalent anion. The anion X is, for example, a halogen anion. The halogen anion is, for example, chlorine, bromine, or iodine.

Different sites of the cation A may include different ions, and so may different sites of the cation B and different sites of the anion X.

The perovskite compound may be at least one selected from the group consisting of CsSnI₃, CsGeI₃, and CsPbI₃.

The photoelectric conversion material of the second embodiment may further include SnF₂. When the perovskite compound includes a Sn cation as the divalent cation, the further included SnF₂ can reduce Sn defects. Hence, when the photoelectric conversion material of the second embodiment further includes SnF₂, the photoelectric conversion efficiency can be improved.

The photoelectric conversion material of the second embodiment can be manufactured, for example, by the following method.

First, a precursor solution of the photoelectric conversion material of the second embodiment is prepared. The precursor solution of the photoelectric conversion material of the second embodiment can be prepared, for example, by mixing a solution in which the phosphonium salt and/or the sulfonium salt are dissolved with a precursor solution of the perovskite compound. Examples of the raw material used to prepare the precursor solution of the photoelectric conversion material of the second embodiment include a compound including a monovalent cation such as CsI and a halogen anion, a compound including a divalent cation such as SnI₂ and a halogen anion, and a compound including a divalent cation such as SnF₂ and a F anion. As a solvent, one solvent may be used, or a solvent mixture containing a plurality of solvents may be used. The solvent may be, for example, a solvent mixture containing DMF and DMSO.

The precursor solution of the photoelectric conversion material of the second embodiment may be prepared, for example, by preparing: a first solution containing a compound including a monovalent cation and a halogen anion, a compound including a divalent cation and a halogen anion, and a solvent; a second solution containing a compound including a divalent cation and a F anion and a solvent; and a third solution containing the phosphonium salt and/or the sulfonium salt and a solvent and then mixing the second solution and the third solution with the first solution.

Next, the prepared precursor solution of the photoelectric conversion material of the second embodiment is applied to a base, for example, by a coating technique such as spin coating, and the resulting coating film is left to stand still for a given period of time for growth of a crystal nucleus in the coating film. This is followed by baking of the film obtained by the spin coating. When, for example, a solvent mixture containing DMF and DMSO (e.g., at a volume ratio of DMF:DMSO=1:4) is used, for example, the coating film may be baked at a temperature of approximately 120° C. or higher and approximately 220° C. or lower after a crystal nucleus is grown in the coating film at room temperature.

### Other Embodiments

### (Supplement)

The description of the above embodiments discloses the following techniques.

### (Technique 1)

A photoelectric conversion element manufacturing method includes:
forming a first electrode;
forming a photoelectric conversion layer; and
forming a second electrode, wherein
the forming of the photoelectric conversion layer includes:
   preparing a solution mixture by mixing a solution in which at least one selected from the group consisting of a phosphonium salt and a sulfonium salt is dissolved with a precursor solution of a perovskite compound; and
   forming a coating film using the solution mixture.

A new photoelectric conversion element capable of improving the photoelectric conversion efficiency can be provided by this manufacturing method.

### (Technique 2)

The photoelectric conversion element manufacturing method according to Technique 1, wherein
in the forming of the photoelectric conversion layer, the preparing of the solution mixture includes:
   preparing: a first solution containing a compound including a monovalent cation and a halogen anion, a compound including a divalent cation and a halogen anion, and a solvent; a second solution containing a compound including a divalent cation and a F anion and a solvent; and a third solution containing the at least one selected from the group consisting of the phosphonium salt and the sulfonium salt and a solvent, and
   mixing the second solution and the third solution with the first solution.

The photoelectric conversion efficiency of a photoelectric conversion element manufactured by this manufacturing method can be further improved.

### (Technique 3)

The photoelectric conversion element manufacturing method according to Technique 1 or 2, wherein
the forming of the photoelectric conversion layer further includes baking the coating film.

The photoelectric conversion efficiency of a photoelectric conversion element manufactured by this manufacturing method can be further improved.

### (Technique 4)

A photoelectric conversion element includes:
a first electrode;
a photoelectric conversion layer; and a second electrode, wherein the photoelectric conversion layer includes a perovskite compound and at least one selected from the group consisting of a phosphonium ion and a sulfonium ion.

This configuration can provide a new photoelectric conversion element capable of improving photoelectric conversion efficiency.

### (Technique 5)

The photoelectric conversion element according to Technique 4, wherein the perovskite compound has an average primary particle diameter of 1 μm or more.

The photoelectric conversion efficiency of the photoelectric conversion element configured as above can be further improved.

### (Technique 6)

The photoelectric conversion element according to Technique 4 or 5, wherein the at least one selected from the group consisting of the phosphonium ion and the sulfonium ion is present between crystals of the perovskite compound.

The photoelectric conversion efficiency of the photoelectric conversion element configured as above can further be improved.

### (Technique 7)

The photoelectric conversion element according to any one of Techniques 4 to 6, wherein energy of a photoluminescence peak of the photoelectric conversion layer is substantially equal to energy of a photoluminescence peak of the perovskite compound.

The photoelectric conversion efficiency of the photoelectric conversion element configured as above can further be improved without changing its light absorption properties (e.g., the wavelength of light it absorbs).

### (Technique 8)

The photoelectric conversion element according to any one of Techniques 4 to 7, wherein
the phosphonium ion is a cation forming a portion of a phosphonium salt,
the sulfonium ion is a cation forming a portion of a sulfonium salt, and
at least one selected from the group consisting of the phosphonium salt and the sulfonium salt includes at least one selected from the group consisting of an alkyl group and an aryl group.

The photoelectric conversion efficiency of the photoelectric conversion element configured as above can further be improved.

### (Technique 9)

The photoelectric conversion element according to Technique 8, wherein
the at least one selected from the group consisting of the phosphonium salt and the sulfonium salt includes an alkyl group, and
the number of carbon atoms in the alkyl group is 1 or more and 10 or less.

The photoelectric conversion efficiency of the photoelectric conversion element configured as above can further be improved.

### (Technique 10)

The photoelectric conversion element according to Technique 8 or 9, wherein the phosphonium salt includes a quaternary phosphonium salt.

The photoelectric conversion efficiency of the photoelectric conversion element configured as above can further be improved.

### (Technique 11)

The photoelectric conversion element according to Technique 8 or 9, wherein the sulfonium salt includes a tertiary sulfonium salt.

The photoelectric conversion efficiency of the photoelectric conversion element configured as above can further be improved.

### (Technique 12)

The photoelectric conversion element according to any one of Techniques 8 to 11, wherein the at least one selected from the group consisting of the phosphonium salt and the sulfonium salt includes a halogen element.

The photoelectric conversion efficiency of the photoelectric conversion element configured as above can further be improved.

### (Technique 13)

The photoelectric conversion element according to Technique 12, wherein the halogen element includes iodine.

The photoelectric conversion efficiency of the photoelectric conversion element configured as above can further be improved.

### (Technique 14)

The photoelectric conversion element according to any one of Techniques 8 to 13, wherein the phosphonium salt includes an iodine-containing phosphonium salt.

The photoelectric conversion efficiency of the photoelectric conversion element configured as above can further be improved.

### (Technique 15)

The photoelectric conversion element according to Technique 14, wherein the iodine-containing phosphonium salt includes at least one selected from the group consisting of tributylmethylphosphonium iodide, methyltriphenylphosphonium iodide, ethyltriphenylphosphonium iodide, and isopropyltriphenylphosphonium iodide.

The photoelectric conversion efficiency of the photoelectric conversion element configured as above can further be improved.

### (Technique 16)

The photoelectric conversion element according to any one of Techniques 8 to 15, wherein the sulfonium salt includes an iodine-containing sulfonium salt.

The photoelectric conversion efficiency of the photoelectric conversion element configured as above can further be improved.

### (Technique 17)

The photoelectric conversion element according to Technique 16, wherein the iodine-containing sulfonium salt includes at least one selected from the group consisting of tributylsulfonium iodide and trimethylsulfonium iodide.

The photoelectric conversion efficiency of the photoelectric conversion element configured as above can further be improved.

### (Technique 18)

The photoelectric conversion element according to any one of Techniques 8 to 17, wherein a molar ratio of the phosphonium salt or the sulfonium salt to the perovskite compound is 0.01 or more and 0.50 or less.

The photoelectric conversion efficiency of the photoelectric conversion element configured as above can further be improved.

### (Technique 19)

The photoelectric conversion element according to Technique 18, wherein the molar ratio is 0.05 or more and 0.10 or less.

The photoelectric conversion efficiency of the photoelectric conversion element configured as above can further be improved.

### (Technique 20)

The photoelectric conversion element according to any one of Techniques 4 to 19, wherein the perovskite compound includes a halogen anion.

The photoelectric conversion efficiency of the photoelectric conversion element configured as above can further be improved.

### (Technique 21)

The photoelectric conversion element according to any one of Techniques 4 to 20, wherein
the perovskite compound is formed of a monovalent cation, a divalent cation, and a halogen anion, and
the divalent cation includes at least one selected from the group consisting of a Sn cation, a Ge cation, and a Pb cation.

The photoelectric conversion efficiency of the photoelectric conversion element configured as above can further be improved.

### (Technique 22)

The photoelectric conversion element according to Technique 21, wherein the monovalent cation includes 50 mol % or more of an inorganic cation.

The photoelectric conversion efficiency of the photoelectric conversion element configured as above can further be improved.

### (Technique 23)

The photoelectric conversion element according to Technique 21 or 22, wherein
the perovskite compound is at least one selected from the group consisting of CsSnI₃, CsGeI₃, and CsPbI₃.

The photoelectric conversion efficiency of the photoelectric conversion element configured as above can further be improved.

### (Technique 24)

The photoelectric conversion element according to any one of Techniques 4 to 23, wherein the photoelectric conversion layer further includes SnF₂.

The photoelectric conversion efficiency of the photoelectric conversion element configured as above can further be improved.

### (Technique 25)

A photoelectric conversion material includes a perovskite compound and a phosphonium ion.

This configuration can provide a new photoelectric conversion material capable of improving photoelectric conversion efficiency.

### (Technique 26)

The photoelectric conversion material according to Technique 25, wherein the perovskite compound has an average primary particle diameter of 1 μm or more.

The photoelectric conversion efficiency of the photoelectric conversion material configured as above can further be improved.

### (Technique 27)

A photoelectric conversion material includes a perovskite compound and a sulfonium ion.

This configuration can provide a new photoelectric conversion material capable of improving photoelectric conversion efficiency.

### (Technique 28)

The photoelectric conversion material according to Technique 27, wherein the perovskite compound has an average primary particle diameter of 1 μm or more.

The photoelectric conversion efficiency of the photoelectric conversion material configured as above can further be improved.

### EXAMPLES

The present disclosure will be described hereinafter in more details with reference to Examples and Comparative Examples.

Hereinafter, preparation of raw material solutions of photoelectric conversion layers and hole transport layers and formation of photoelectric conversion layers and hole transport layers were carried out in a glove box in which the oxygen concentration and the moisture concentration were each 1 ppm or lower.

### Production of Photoelectric Conversion Element (Example 1)

First, a glass substrate was prepared. The substrate plays the role of a supporting material for the photoelectric conversion element of the present disclosure.

An indium tin oxide (ITO) layer was formed on the substrate by sputtering. Furthermore, an antimony tin oxide (ATO) layer was formed on the ITO layer by sputtering. A first electrode was formed in this manner.

Next, a compact titanium oxide (TiO₂) layer was formed on the ATO layer of the first electrode by sputtering. This compact titanium oxide (TiO₂) layer corresponds, for example, to the electron transport layer described in the above first embodiment.

Next, 0.45 g of a titanium oxide paste 30NR-D (manufactured by Gratcell Solar Materials Pty Ltd.) was dissolved in 2 mL of a butanol solution. The resulting solution was applied to the electron transport layer by spin coating, followed by baking at 500° C. for 20 minutes. A porous titanium oxide layer was formed in this manner. The spin coating was performed at 4000 rpm for 20 seconds. It should be noted that both the above compact titanium oxide layer and the above porous titanium oxide layer have an electron transport capability. Therefore, it can be considered that the electron transport layer is composed of the above compact titanium oxide layer and the above porous titanium oxide layer.

A precursor solution of a photoelectric conversion material was applied to the porous layer by spin coating, and was left to stand still at room temperature for 10 minutes. This was followed by baking the coating film at 120° C. for 1 minute, 160° C. for 1 minute, and then 200° C. for 10 minutes. A photoelectric conversion layer was formed in this manner. Toluene serving as a poor solvent was dropped during the spin coating for film formation at 5000 rpm for 40 seconds.

The precursor solution of the photoelectric conversion material was obtained in the following manner. First, SnI₂ and CsI were added to a solvent mixture containing DMF and DMSO (at a volume ratio of DMF:DMSO=1:4) to prepare a 1.5 mol/L first solution. Next, SnF₂ was added to a solvent mixture containing DMF and DMSO (at a volume ratio of DMF:DMSO=1:4) to prepare a 1.5 mol/L second solution. Furthermore, TBMPI was added to a solvent mixture containing DMF and DMSO (at a volume ratio of DMF:DMSO=1:4) to prepare a 1.5 mol/L third solution. The second and third solutions were added to the first solution. The precursor solution of the photoelectric conversion material was obtained in this manner.

In Example 1, the precursor solution obtained by adding the second solution at an addition concentration of 16 mol % and the third solution at an addition concentration of 5 mol % relative to the first solution was used. The photoelectric conversion layer was obtained, as described above, by baking the coating film formed using the precursor solution at 120° C. for 1 minute, 160° C. for 1 minute, and then 200° C. for 10 minutes.

Next, a raw material solution of a hole transport layer was applied to the photoelectric conversion layer by spin coating. A hole transport layer was formed in this manner. The raw material solution of the hole transport layer was prepared by dissolving 18 mg of poly [bis(4-phenyl) (2,4,6-triphenyl)amine] (PTAA) in 1 mL of chlorobenzene. The spin coating was performed at 4000 rpm for 20 seconds.

Subsequently, a gold film was formed on the hole transport layer by deposition. A 200 nm-thick second electrode was formed in this manner.

Finally, a UV-curable epoxy resin was applied to a periphery of the substrate, another glass substrate was placed thereon, and the resulting laminate was irradiated with UV. The epoxy resin was thereby cured to encapsulate the electricity generation constituents.

### (Example 2)

A photoelectric conversion element was produced in the same manner as in Example 1, except that in production of the photoelectric conversion layer, the third solution was added at an addition concentration of 7.5 mol % to prepare the precursor solution of the photoelectric conversion material.

### (Example 3)

A photoelectric conversion element was produced in the same manner as in Example 1, except that in production of the photoelectric conversion layer, the baking temperature at which the coating film formed of the precursor solution of the photoelectric conversion material was baked was 120° C. for 1 minute, 160° C. for 1 minute, and then 180° C. for 10 minutes.

### Example 4

A photoelectric conversion element was produced in the same manner as in Example 1, except that in production of the photoelectric conversion layer, the third solution was added at an addition concentration of 7.5 mol % to prepare the precursor solution of the photoelectric conversion material and the baking temperature at which the coating film formed of the precursor solution of the photoelectric conversion material was baked was 120° C. for 1 minute, 160° C. for 1 minute, and then 180° C. for 10 minutes.

### (Example 5)

A photoelectric conversion element was produced in the same manner as in Example 1, except that in production of the photoelectric conversion layer, the third solution was added at an addition concentration of 7.5 mol % to prepare the precursor solution of the photoelectric conversion material and the baking temperature at which the coating film formed of the precursor solution of the photoelectric conversion material was baked was 120° C. for 1 minute, 160° C. for 1 minute, and then 220° C. for 10 minutes.

### (Example 6)

A photoelectric conversion element was produced in the same manner as in Example 1, except that in production of the photoelectric conversion layer, TBSI was used as the solute of the third solution instead of TBMPI to prepare the precursor solution of the photoelectric conversion material and the baking temperature at which the coating film formed of the precursor solution of the photoelectric conversion material was baked was 120° C. for 1 minute, 160° C. for 1 minute, and then 180° C. for 10 minutes.

### (Example 7)

A photoelectric conversion element was produced in the same manner as in Example 1, except that in production of the photoelectric conversion layer, TBSI was used as the solute of the third solution instead of TBMPI to prepare the precursor solution of the photoelectric conversion material.

### Comparative Example 1

A photoelectric conversion element was produced in the same manner as in Example 1, except that the photoelectric conversion layer was produced by the following method.

In Comparative Example 1, the precursor solution of the photoelectric conversion layer was obtained in the following manner. First, SnI₂ and CsI were added to a solvent mixture containing DMF and DMSO (at a volume ratio of DMF:DMSO=1:1) to prepare a 0.9 mol/L first solution. Next, SnF₂ was added to a solvent mixture containing DMF and DMSO (at a volume ratio of DMF:DMSO=1:1) to prepare a 0.9 mol/L second solution. The second solution was added to the first solution. The second solution was added at an addition concentration of 16 mol % relative to the first solution. The precursor solution was obtained in this manner. That is, no third solution (namely, a solution containing a phosphonium salt or a sulfonium salt) was added in Comparative Example 1 to prepare the precursor solution of the photoelectric conversion material.

A precursor solution of a photoelectric conversion material was applied to the porous layer by spin coating, and was left to stand still at room temperature for 10 minutes. This was followed by baking the coating film at 240° C. for 10 minutes. A photoelectric conversion layer was formed in this manner. Toluene serving as a poor solvent was dropped during the spin coating for film formation at 5000 rpm for 40 seconds.

### Comparative Example 2

A photoelectric conversion element was produced in the same manner as in Comparative Example 1, except that in production of the photoelectric conversion layer, the baking temperature for the coating film was 200° C.

### <Evaluation of Characteristics of Photoelectric Conversion Element>

For the photoelectric conversion elements of Examples 1 to 7 and Comparative Examples 1 and 2, current-voltage characteristics (namely, I-V characteristics) were evaluated.

A solar simulator (manufactured by Bunkoukeiki Co., Ltd.) and an electrochemical analyzer ALS (manufactured by BAS Inc.) were used for the evaluation of the characteristics. The photoelectric conversion elements were irradiated with one sun of simulated sunlight. The output of the solar simulator was set to 100 mW/cm². The I-V characteristics of the photoelectric conversion elements were measured by measuring output current values using the electrochemical analyzer under varying applied voltage.

Table 1 shows the measurement results. The symbol n represents conversion efficiency. The symbol J_{SC} represents short-circuit current density. The symbol V_{oc} represents open-circuit voltage. The open-circuit voltage shown in Table 1 is the higher value of those in forward sweep and reverse sweep. The symbol FF represents the fill factor. Moreover, Table 1 shows the additive (namely, the phosphonium salt or the sulfonium salt) added to CsSnI₃ being the perovskite compound forming the photoelectric conversion layer, the addition concentration of the additive, and the baking temperature for formation of the photoelectric conversion layer. In the table, the molar concentration of the phosphonium salt added or the sulfonium salt added is shown on the basis of feed amount. In addition, a molar ratio of the phosphonium salt or the sulfonium salt to the perovskite compound can be determined from a feed ratio of the raw materials. A preliminary experiment by the present applicant has confirmed that the molar ratio of the phosphonium salt or the sulfonium salt to the perovskite compound determined from the feed ratio of the raw materials is not greatly different from that determined using a composition ratio determined by element analysis of the photoelectric conversion layer produced. In the table, the phosphonium salt and the sulfonium salt are referred to as “organic salt”.

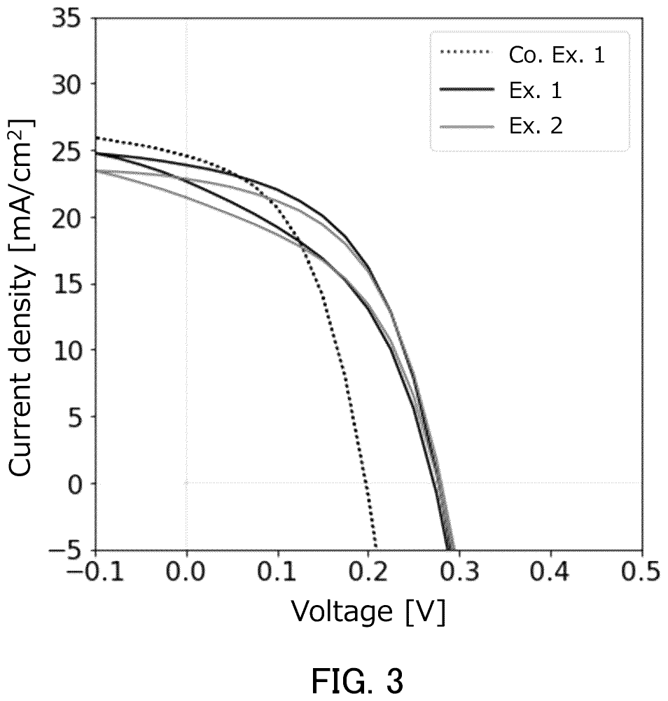

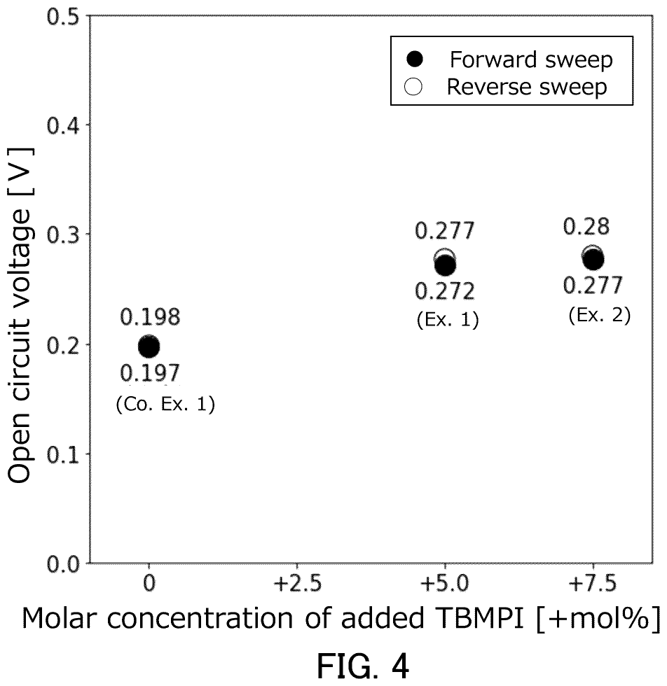

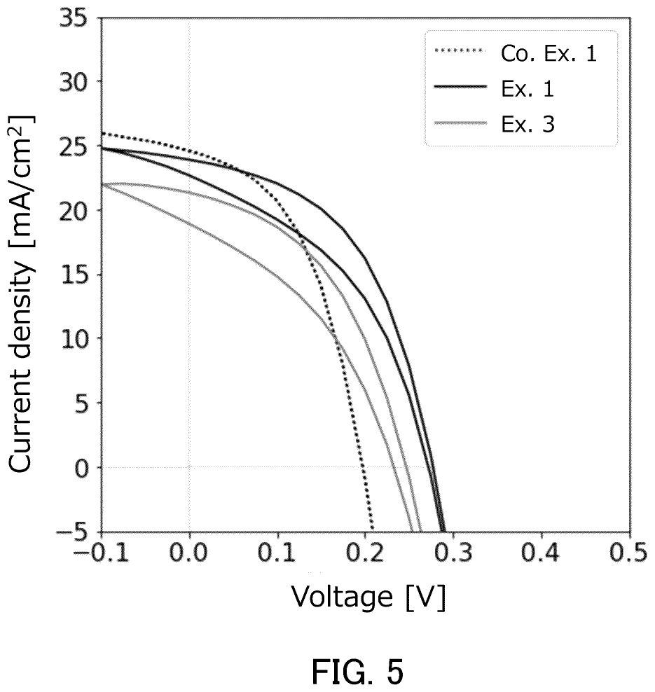

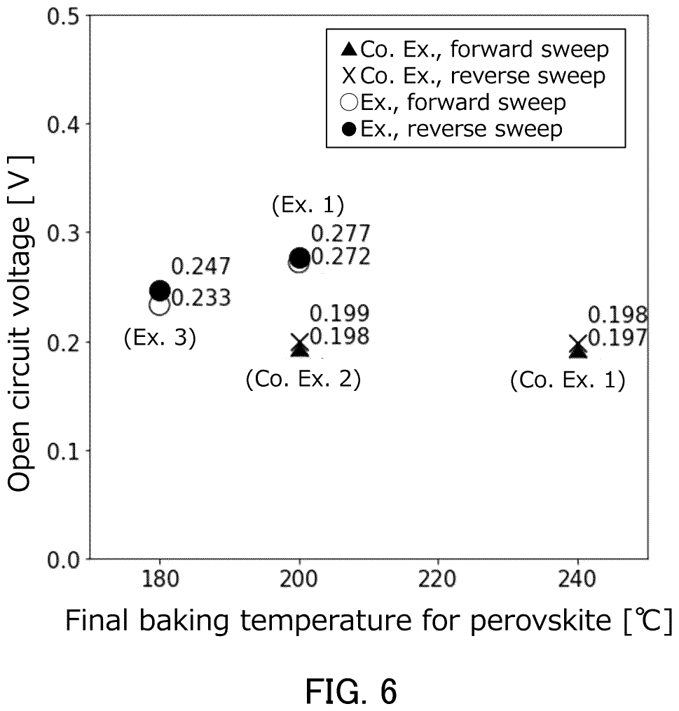

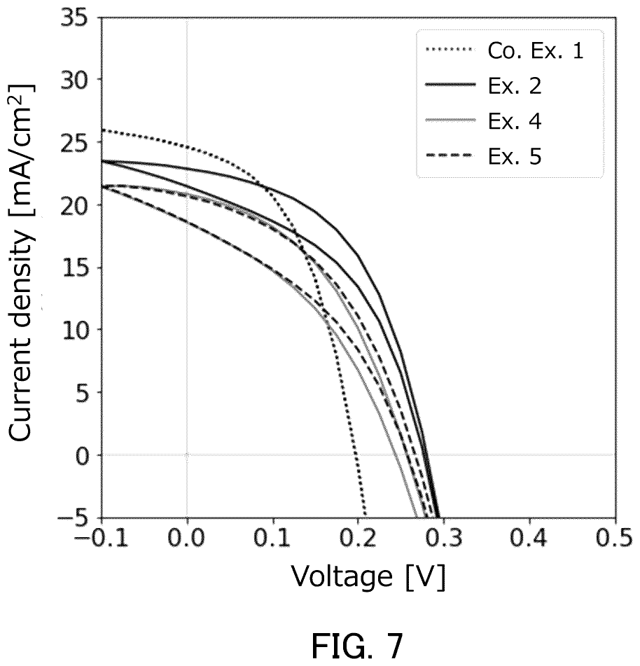

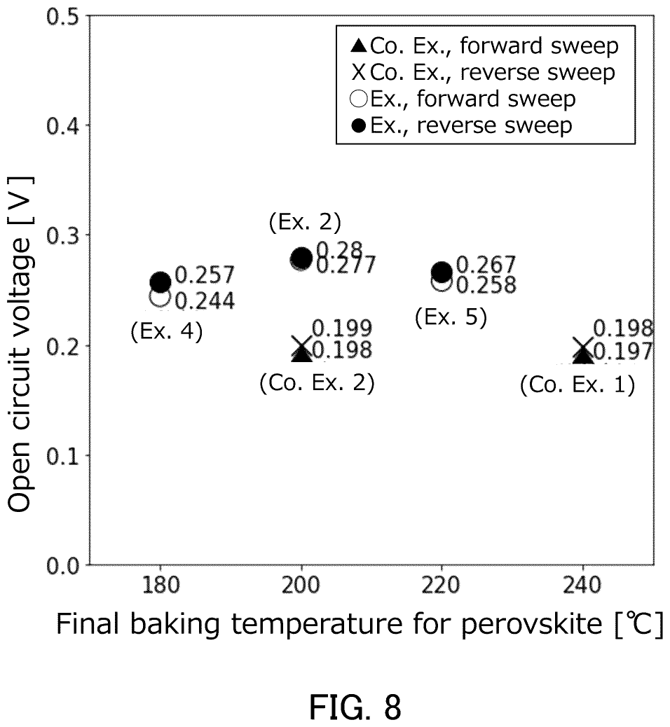

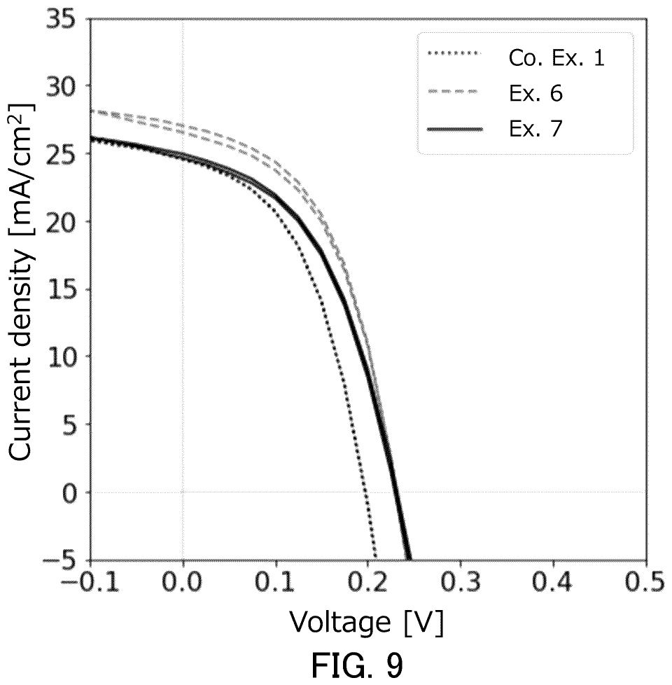

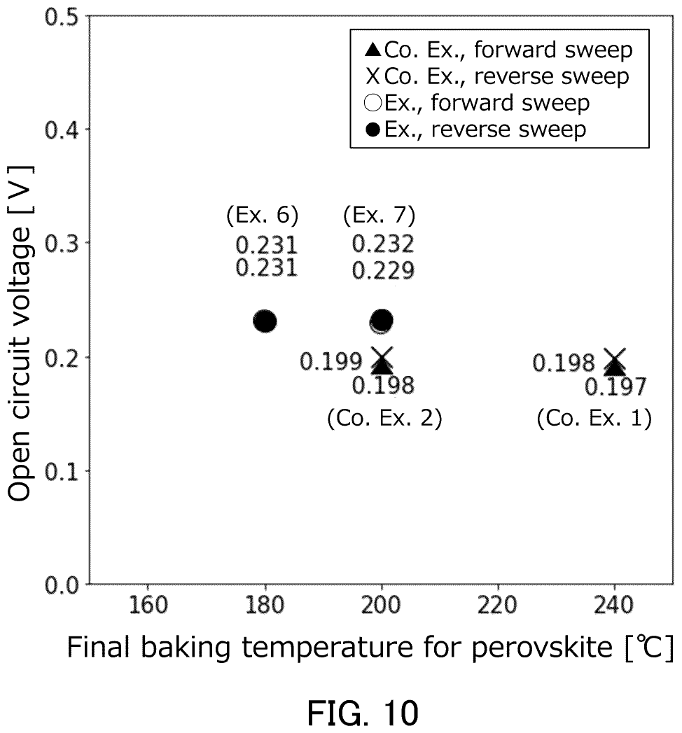

FIG. 3 is a graph showing the I-V characteristics of the photoelectric conversion elements of Example 1, Example 2, and Comparative Example 1. FIG. 4 is a graph showing the open-circuit voltages of the photoelectric conversion elements of Example 1, Example 2, and Comparative Example 1. Specifically, FIG. 4 is a graph showing an increase in open-circuit voltage Voc attributable to the addition concentration of TBMPI added to CsSnI₃. FIG. 5 is a graph showing the I-V characteristics of the photoelectric conversion elements of Example 1, Example 3, and Comparative Example 1. FIG. 6 is a graph showing the open-circuit voltages of the photoelectric conversion elements of Example 1, Example 3, Comparative Example 1, and Comparative Example 2. Specifically, FIG. 6 is a graph showing an increase in open-circuit voltage Voc attributable to the final baking temperature for the photoelectric conversion layer obtained by adding TBMPI at an addition concentration of 5 mol %. FIG. 7 is a graph showing the I-V characteristics of the photoelectric conversion elements of Example 2, Example 4, Example 5, and Comparative Example 1. FIG. 8 is a graph showing the open-circuit voltages of the photoelectric conversion elements of Example 2, Example 4, Example 5, Comparative Example 1, and Comparative Example 2. Specifically, FIG. 8 is a graph showing an increase in open-circuit voltage Voc attributable to the final baking temperature for the photoelectric conversion layer obtained by adding TBMPI at an addition concentration of 7.5 mol %. FIG. 9 is a graph showing the I-V characteristics of the photoelectric conversion elements of Example 6, Example 7, and Comparative Example 1. FIG. 10 is a graph showing the open-circuit voltages of the photoelectric conversion elements of Example 6, Example 7, Comparative Example 1, and Comparative Example 2. Specifically, FIG. 10 is a graph showing an increase in open-circuit voltage Voc attributable to the final baking temperature for the photoelectric conversion layer obtained by adding TBSI at an addition concentration of 5 mol %.

TABLE 1

| | Production of photoelectric | | | | | | |
|---|---|---|---|---|---|---|---|
| | conversion layer | | | | | | |
| | Addition | Addition | | Properties of photoelectric | | | |
| | of | concentration | Final baking | conversion element | | | |
| | organic | of organic salt | temperature | η | J_{SC} | Voc | |
| | salt | (mol %) | (° C.) | (%) | (mA/cm²) | (V) | FF |
| Example 1 | Added | 5 | 200 | 3.24 | 23.860 | 0.277 | 0.490 |
| | (TBMPI) | | | | | | |
| Example 2 | Added | 7.5 | 200 | 3.18 | 22.820 | 0.280 | 0.497 |
| | (TBMPI) | | | | | | |
| Example 3 | Added | 5 | 180 | 2.34 | 21.310 | 0.247 | 0.446 |
| | (TBMPI) | | | | | | |
| Example 4 | Added | 7.5 | 180 | 2.29 | 20.810 | 0.257 | 0.429 |
| | (TBMPI) | | | | | | |
| Example 5 | Added | 7.5 | 220 | 2.38 | 20.620 | 0.267 | 0.432 |
| | (TBMPI) | | | | | | |
| Example 6 | Added | 5 | 180 | 3.01 | 26.520 | 0.231 | 0.489 |
| | (TBSI) | | | | | | |
| Example 7 | Added | 5 | 200 | 2.67 | 24.920 | 0.232 | 0.462 |
| | (TBSI) | | | | | | |
| Comparative | Not | 0 | 240 | 2.27 | 24.530 | 0.197 | 0.470 |
| Example 1 | added | | | | | | |
| Comparative | Not | 0 | 200 | 2.09 | 24.040 | 0.198 | 0.440 |
| Example 2 | added | | | | | | |

As shown in Table 1, the photoelectric conversion elements of Examples 1 to 7 including the photoelectric conversion layer formed using the precursor solution of the photoelectric conversion material including the phosphonium salt and/or the sulfonium salt had high conversion efficiency, compared to the photoelectric conversion elements of Comparative Examples 1 and 2 including the photoelectric conversion layer formed using the precursor solution of the photoelectric conversion material including neither a phosphonium salt nor a sulfonium salt.

According to a comparison between Examples 1 and 2 and Comparative Examples 1 and 2, high conversion efficiency was achieved when the addition concentration of TBMPI was 5 mol % and 7.5 mol %. As shown in Table 1 and FIGS. 3 and 4, the open-circuit voltage increased for the photoelectric conversion elements of Examples 1 and 2, compared to the photoelectric conversion elements of Comparative Examples 1 and 2. Because of this, the photoelectric conversion elements of Examples 1 and 2 were able to achieve conversion efficiencies approximately 1% higher than those of the photoelectric conversion elements of Comparative Examples 1 and 2.

According to a comparison between Examples 1 and 3 and Comparative Examples 1 and 2, particularly high conversion efficiency was achieved when the final baking temperature for the photoelectric conversion layer obtained by adding TBMPI at an addition concentration of 5 mol % was 200° C. As shown in FIGS. 5 and 6, the open-circuit voltage increased for the photoelectric conversion elements of Examples 1 and 3, compared to the photoelectric conversion elements of Comparative Examples 1 and 2. Because of this, the photoelectric conversion elements of Examples 1 and 3 were able to achieve high conversion efficiency compared to the photoelectric conversion elements of Comparative Examples 1 and 2. In particular, the photoelectric conversion element of Example 1 was able to achieve a high conversion efficiency approximately 1% higher than those of the photoelectric conversion elements of Comparative Examples 1 and 2.

According to a comparison between Examples 2, 4, and 5 and Comparative Examples 1 and 2, also in the case where TBMPI was added at 7.5 mol %, particularly high conversion efficiency was achieved in Example 2 in which the final baking temperature for the photoelectric conversion layer was 200° C. As shown in FIGS. 7 and 8, the open-circuit voltage increased for the photoelectric conversion elements of Examples 2, 4, and 5, compared to the photoelectric conversion elements of Comparative Examples 1 and 2. Because of this, the photoelectric conversion elements of Examples 2, 4, and 5 were able to achieve high conversion efficiency compared to the photoelectric conversion elements of Comparative Examples 1 and 2. In particular, the photoelectric conversion element of Example 2 was able to achieve a high conversion efficiency approximately 1% higher than those of the photoelectric conversion elements of Comparative Examples 1 and 2.

According to a comparison between Examples 6 and 7 and Comparative Examples 1 and 2, in the case where TBSI was added at 5 mol %, particularly high conversion efficiency was achieved when the final baking temperature for the photoelectric conversion layer was 180° C. As shown in Table 1 and FIGS. 9 and 10, the open-circuit voltage and the short-circuit current density increased for the photoelectric conversion elements of Examples 6 and 7, compared to the photoelectric conversion elements of Comparative Examples 1 and 2. Because of this, the photoelectric conversion elements of Examples 6 and 7 were able to achieve high conversion efficiency compared to the photoelectric conversion elements of Comparative Examples 1 and 2. In particular, the photoelectric conversion element of Example 6 was able to achieve a high conversion efficiency approximately 1% higher than those of the photoelectric conversion elements of Comparative Examples 1 and 2.

### <PL Lifetime Evaluation of Photoelectric Conversion Layer>

In the same manner as for the photoelectric conversion layers of the photoelectric conversion elements, the following three measurement samples were produced to measure PL lifetimes of their photoelectric conversion layers.

After the precursor solution (namely, CsSnI₃+16 mol % SnF₂) of the photoelectric conversion material as used in Comparative Example 1 and Comparative Example 2 was applied to a glass substrate by spin coating, the coating film was baked at 200° C., 220° C., or 240° C. for 10 minutes. Chlorobenzene serving as a poor solvent was dropped during the spin coating for film formation at 5000 rpm for 30 seconds. Next, a UV-curable epoxy resin was applied to a periphery of the substrate, another glass substrate was placed thereon, and the resulting laminate was irradiated with UV. The epoxy resin was thereby cured to encapsulate the measurement sample.

After the precursor solution (namely, CsSnI₃+16 mol % SnF₂+5 mol % TBMPI) of the photoelectric conversion material as used in Example 1 was applied to a glass substrate by spin coating, the coating film was baked at 120° C. for 1 minute, 160° C. for 1 minute, and then 200° C. for 10 minutes. Toluene serving as a poor solvent was dropped during the spin coating for film formation at 5000 rpm for 40 seconds. Next, a UV-curable epoxy resin was applied to a periphery of the substrate, another glass substrate was placed thereon, and the resulting laminate was irradiated with UV. The epoxy resin was thereby cured to encapsulate the measurement sample.

After the precursor solution (namely, CsSnI₃+16 mol % SnF₂+5 mol % TBSI) of the photoelectric conversion material as used in Examples 6 and 7 was applied to a glass substrate by spin coating, the coating film was baked at 120° C. for 1 minute, 160° C. for 1 minute, and then 180° C. for 10 minutes. Toluene serving as a poor solvent was dropped during the spin coating for film formation at 5000 rpm for 40 seconds. Next, a UV-curable epoxy resin was applied to a periphery of the substrate, another glass substrate was placed thereon, and the resulting laminate was irradiated with UV. The epoxy resin was thereby cured to encapsulate the measurement sample.

The PL lifetimes were measured using a near-infrared fluorescence lifetime measurement apparatus (C7990 VIS/NIR manufactured by Hamamatsu Photonics K.K.). A photosensor module being one of constituent units thereof was H7422. The measurement results were analyzed with fluorescence lifetime software U8167-03.

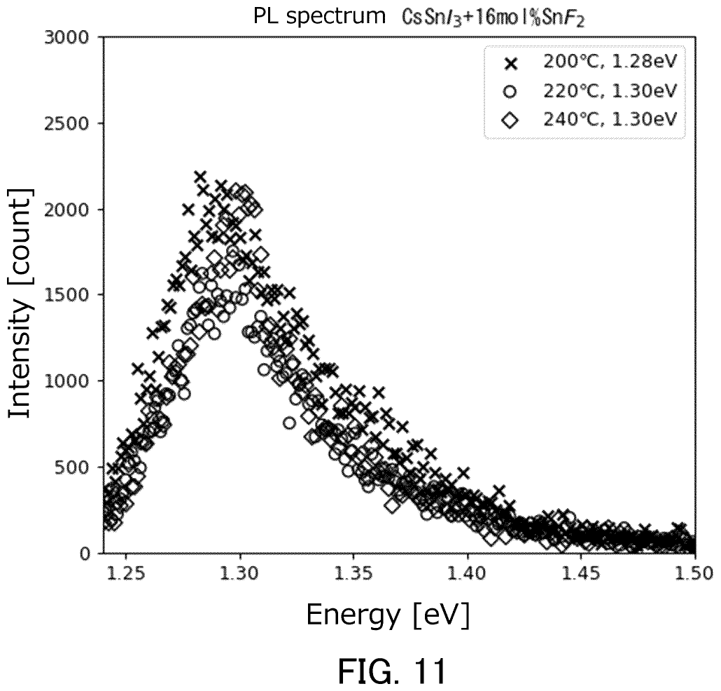

FIG. 11 is a graph showing a PL spectrum of the photoelectric conversion layer alone formed from CsSnI₃+16 mol % SnF₂.

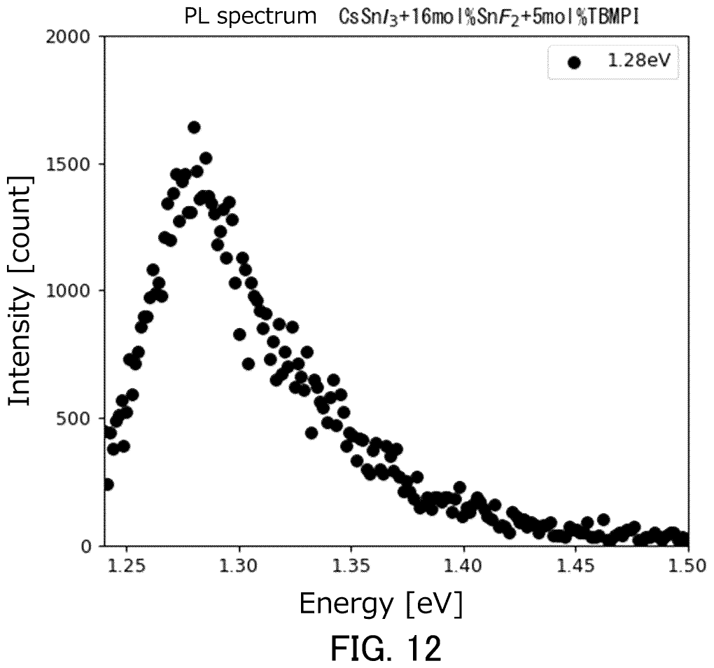

FIG. 12 is a graph showing a PL spectrum of the photoelectric conversion layer alone formed from CsSnI₃+16 mol % SnF₂+5 mol % TBMPI.

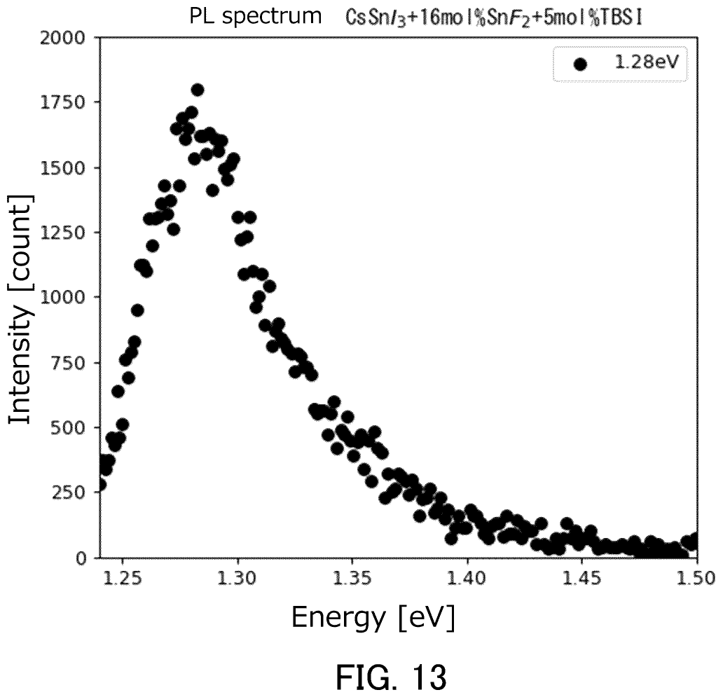

FIG. 13 is a graph showing a PL spectrum of the photoelectric conversion layer alone formed from CsSnI₃+16 mol % SnF₂+5 mol % TBSI.

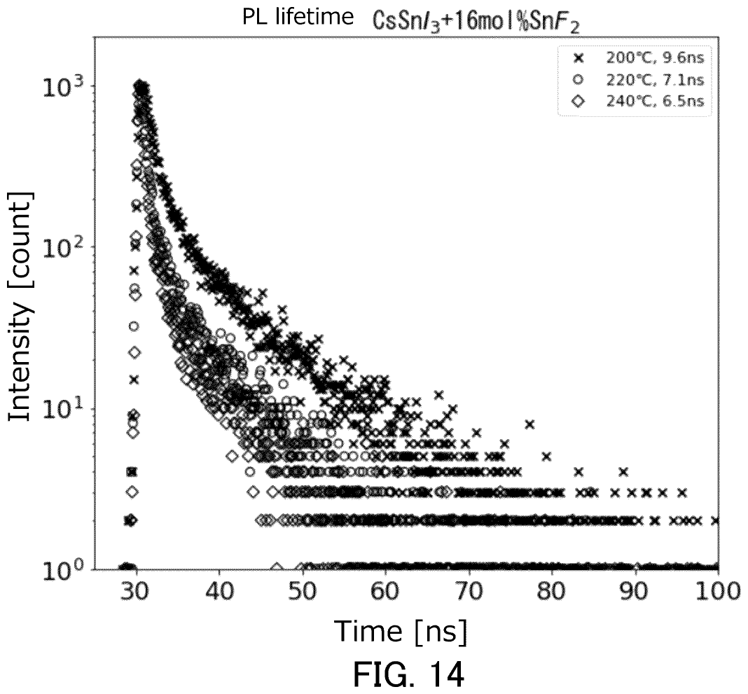

FIG. 14 is a graph showing a PL lifetime of the photoelectric conversion layer alone formed from CsSnI₃+16 mol % SnF₂.

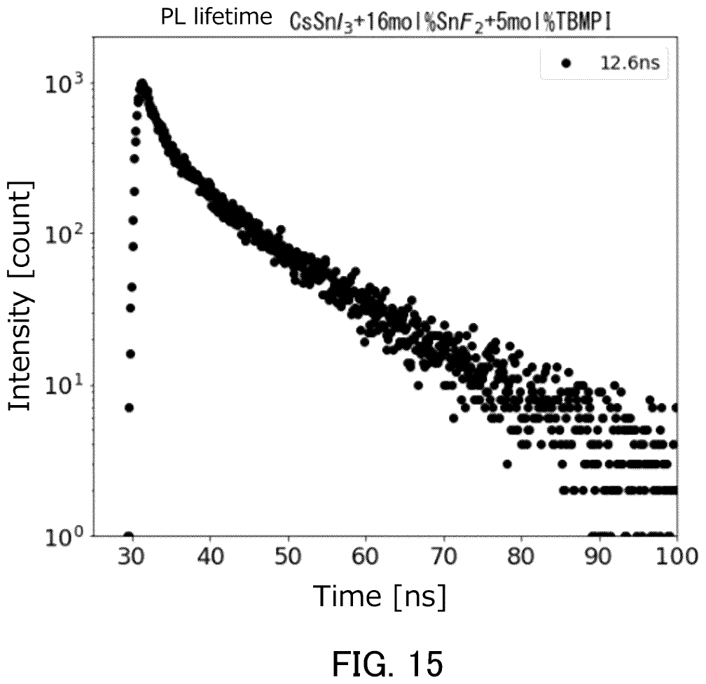

FIG. 15 is a graph showing a PL lifetime of the photoelectric conversion layer alone formed from CsSnI₃+16 mol % SnF₂+5 mol % TBMPI.

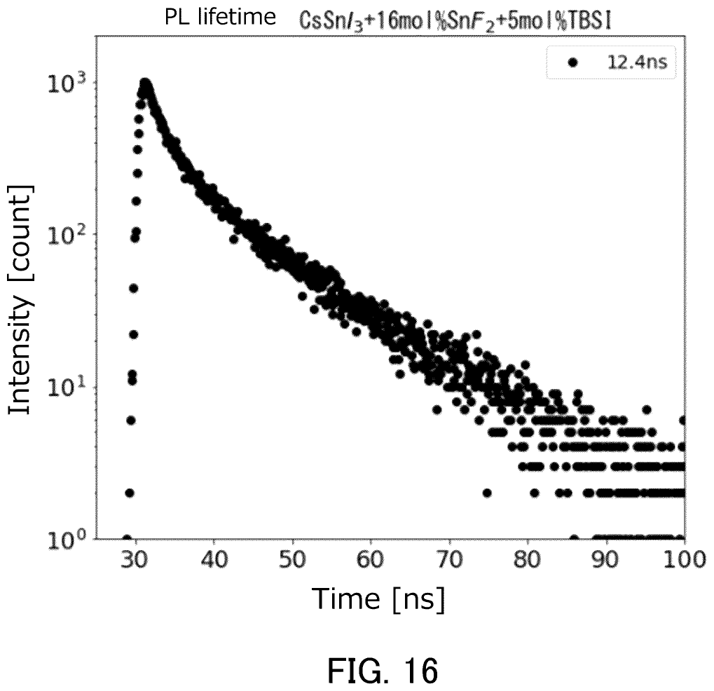

FIG. 16 is a graph showing a PL lifetime of the photoelectric conversion layer alone formed from CsSnI₃+16 mol % SnF₂+5 mol % TBSI.

As is obvious from FIG. 11, a PL peak of the photoelectric conversion layer alone formed from CsSnI₃+16 mol % SnF₂ was from 1.28 eV to 1.30 eV. Moreover, as is obvious from FIG. 12, the PL peak of the photoelectric conversion layer alone obtained by adding TBMPI at 5 mol % to CsSnI₃+16 mol % SnF₂ was 1.28 eV. Furthermore, as is obvious from FIG. 13, the PL peak of the photoelectric conversion layer alone obtained by adding TBSI at 5 mol % to CsSnI₃+16 mol % SnF₂ was 1.28 eV. Thus, the band gap was considered to be almost unchanged by the addition of TBMPI or TBSI.

As is evident from a comparison of the PL lifetime shown in FIG. 15 with the PL lifetime shown in FIG. 14, the PL lifetime of the photoelectric conversion layer was remarkably extended from the range of 6.5 ns to 9.6 ns to 12.6 ns by adding TBMPI at 5 mol % to CsSnI₃+16 mol % SnF₂. As is evident from a comparison of the PL lifetime shown in FIG. 16 with the PL lifetime shown in FIG. 14, the PL lifetime of the photoelectric conversion layer was remarkably extended from the range of 6.5 ns to 9.6 ns to 12.4 ns by adding TBSI at 5 mol % to CsSnI₃+16 mol % SnF₂.

### <Evaluation of SEM Photograph of Photoelectric Conversion Layer>

A photoelectric conversion layer was formed on a porous layer prepared in the same manner as in Example 1.

Specifically, after the precursor solution (namely, CsSnI₃+16 mol % SnF₂) of the photoelectric conversion material as used in Comparative Example 1 and Comparative Example 2 was applied by spin coating to a glass substrate on which layers up to the porous layer were formed, the coating film was baked at 160° C. for 1 minute and then 240° C. for 10 minutes to form a single-layer film. Chlorobenzene serving as a poor solvent was dropped during the spin coating for film formation at 5000 rpm for 30 seconds.

After the precursor solution (namely, CsSnI₃+16 mol % SnF₂+5 mol % TBMPI) of the photoelectric conversion material as used in Example 1 was applied by spin coating to a glass substrate, the coating film was baked at 120° C. for 1 minute, 160° C. for 1 minute, and then 200° C. for 10 minutes to form a single-layer film. Toluene serving as a poor solvent was dropped during the spin coating for film formation at 5000 rpm for 40 seconds.

After the precursor solution (namely, CsSnI₃+16 mol % SnF₂+5 mol % TBSI) of the photoelectric conversion material as used in Example 6 and Example 7 was applied by spin coating to a glass substrate, the coating film was baked at 120° C. for 1 minute, 160° C. for 1 minute, and then 180° C. for 10 minutes to form a single-layer film. Toluene serving as a poor solvent was dropped during the spin coating for film formation at 5000 rpm for 40 seconds.

A SEM photograph was taken using a field-emission scanning electron microscope (SU8200 manufactured by Hitachi High-Tech Corporation).

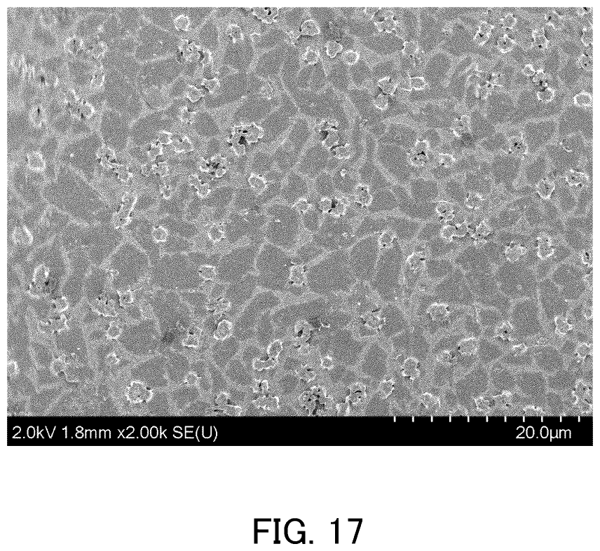

FIG. 17 is a top-view SEM photograph of the photoelectric conversion layer formed from the precursor solution containing CsSnI₃+16 mol % SnF₂.

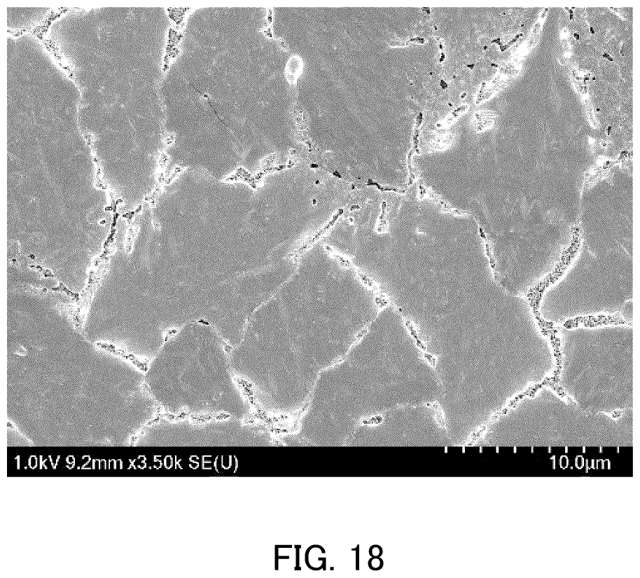

FIG. 18 is a top-view SEM photograph of the photoelectric conversion layer formed from the precursor solution containing CsSnI₃+16 mol % SnF₂+5 mol % TBMPI.

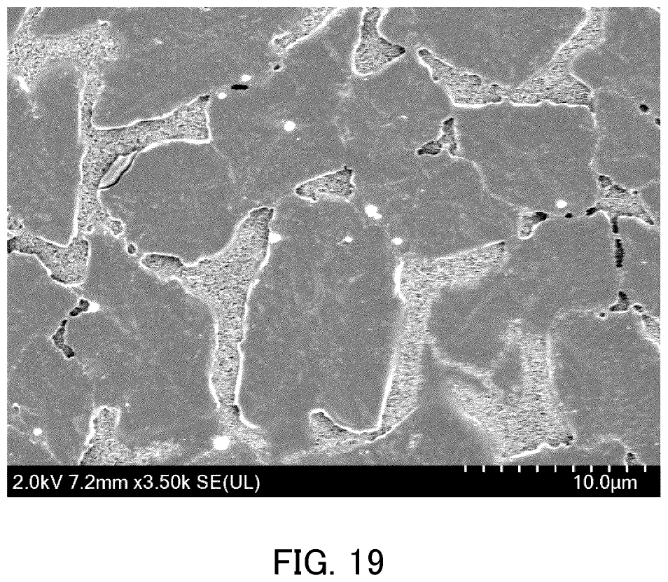

FIG. 19 is a top-view SEM photograph of the photoelectric conversion layer formed from the precursor solution containing CsSnI₃+16 mol % SnF₂+5 mol % TBSI.

As is evident from a comparison of the SEM photographs shown in FIGS. 18 and 19 with the SEM photograph shown in FIG. 17, it has been confirmed that the particle diameters of the crystals in the photoelectric conversion layer (FIG. 18) formed using the precursor solution of the photoelectric conversion material obtained by adding TBMPI and the photoelectric conversion layer (FIG. 19) formed using the precursor solution of the photoelectric conversion material obtained by adding TBSI were larger than those in the photoelectric conversion layer (FIG. 17) formed using the precursor solution of the photoelectric conversion material obtained by adding neither TBMPI nor TBSI. From the particles in each SEM image, 50 particles were selected in order of descending primary particle diameter. The primary particle diameters of the 50 particles were averaged, and the resulting value was employed as the average primary particle diameter. The primary particle diameter of each particle is an average of the maximum diameter and the minimum diameter thereof. The perovskite compound included in the photoelectric conversion layer shown in FIG. 18 and formed using the precursor solution of the photoelectric conversion material obtained by adding TBMPI and the perovskite compound included in the photoelectric conversion layer shown in FIG. 19 and formed using the precursor solution of the photoelectric conversion material obtained by adding TBSI each had an average primary particle diameter of 1 μm or more. From this result, it is considered that the particle diameters of the crystals can be increased by the addition of TBMPI or TBSI and thus grain boundaries in the photoelectric conversion layer are reduced to reduce carrier recombination. It is thought that the photoelectric conversion elements including the photoelectric conversion layers formed using the precursor solutions of the photoelectric conversion materials obtained by adding TBMPI or TBSI were therefore able to improve the photoelectric conversion efficiency.

The particle diameters of the crystals in the perovskite compound included in the photoelectric conversion layer shown in FIG. 18 and formed using the precursor solution of the photoelectric conversion material obtained by adding TBMPI were larger and denser than those in the perovskite compound included in the photoelectric conversion layer shown in FIG. 19 and formed using the precursor solution of the photoelectric conversion material obtained by adding TBSI. Moreover, for the photoelectric conversion layer shown in FIG. 18, the final baking temperature was 200° C., which is the same as that for the photoelectric conversion layer of Example 1. On the other hand, for the photoelectric conversion layer shown in FIG. 19, the final baking temperature was 180° C., which is the same as that for the photoelectric conversion layer of Example 6. The conversion efficiency of the photoelectric conversion element of Example 1 was 3.24%, which is higher than that of the photoelectric conversion element of Example 6, namely, 3.01%. From these results, it is considered that TBMPI increases the particle diameters of crystals and consequently improves the photoelectric conversion efficiency more effectively than TBSI does.

### INDUSTRIAL APPLICABILITY

The photoelectric conversion element provided by the present disclosure can be used, for example, as a solar cell.

What is claimed is:

1. A photoelectric conversion element manufacturing method comprising:
forming a first electrode;
forming a photoelectric conversion layer; and
forming a second electrode, wherein
the forming of the photoelectric conversion layer includes:
preparing a solution mixture by mixing a solution in which at least one selected from the group consisting of a phosphonium salt and a sulfonium salt is dissolved with a precursor solution of a perovskite compound; and
forming a coating film using the solution mixture.

2. The photoelectric conversion element manufacturing method according to claim 1, wherein
in the forming of the photoelectric conversion layer, the preparing of the solution mixture includes:
preparing: a first solution containing a compound including a monovalent cation and a halogen anion, a compound including a divalent cation and a halogen anion, and a solvent; a second solution containing a compound including a divalent cation and a F anion and a solvent; and a third solution containing the at least one selected from the group consisting of the phosphonium salt and the sulfonium salt and a solvent, and
mixing the second solution and the third solution with the first solution.

3. A photoelectric conversion element comprising:
a first electrode;
a photoelectric conversion layer; and
a second electrode, wherein
the photoelectric conversion layer includes a perovskite compound and at least one selected from the group consisting of a phosphonium ion and a sulfonium ion.

4. The photoelectric conversion element according to claim 3, wherein the perovskite compound has an average primary particle diameter of 1 μm or more.

5. The photoelectric conversion element according to claim 3, wherein the at least one selected from the group consisting of the phosphonium ion and the sulfonium ion is present between crystals of the perovskite compound.

6. The photoelectric conversion element according to claim 3, wherein
the phosphonium ion is a cation forming a portion of a phosphonium salt,
the sulfonium ion is a cation forming a portion of a sulfonium salt, and
at least one selected from the group consisting of the phosphonium salt and the sulfonium salt includes at least one selected from the group consisting of an alkyl group and an aryl group.

7. The photoelectric conversion element according to claim 6, wherein
the at least one selected from the group consisting of the phosphonium salt and the sulfonium salt includes an alkyl group, and
the number of carbon atoms in the alkyl group is 1 or more and 10 or less.

8. The photoelectric conversion element according to claim 6, wherein the phosphonium salt includes a quaternary phosphonium salt.

9. The photoelectric conversion element according to claim 6, wherein the sulfonium salt includes a tertiary sulfonium salt.

10. The photoelectric conversion element according to claim 6, wherein the at least one selected from the group consisting of the phosphonium salt and the sulfonium salt includes a halogen element.

11. The photoelectric conversion element according to claim 10, wherein the halogen element includes iodine.

12. The photoelectric conversion element according to claim 6, wherein the phosphonium salt includes an iodine-containing phosphonium salt.

13. The photoelectric conversion element according to claim 12, wherein the iodine-containing phosphonium salt includes at least one selected from the group consisting of tributylmethylphosphonium iodide, methyltriphenylphosphonium iodide, ethyltriphenylphosphonium iodide, and isopropyltriphenylphosphonium iodide.

14. The photoelectric conversion element according to claim 6, wherein the sulfonium salt includes an iodine-containing sulfonium salt.

15. The photoelectric conversion element according to claim 14, wherein the iodine-containing sulfonium salt includes at least one selected from the group consisting of tributylsulfonium iodide and trimethylsulfonium iodide.

16. The photoelectric conversion element according to claim 6, wherein a molar ratio of the phosphonium salt or the sulfonium salt to the perovskite compound is 0.01 or more and 0.50 or less.

17. The photoelectric conversion element according to claim 3, wherein
the perovskite compound is formed of a monovalent cation, a divalent cation, and a halogen anion, and
the divalent cation includes at least one selected from the group consisting of a Sn cation, a Ge cation, and a Pb cation.

18. The photoelectric conversion element according to claim 17, wherein the perovskite compound is at least one selected from the group consisting of CsSnI₃, CsGeI₃, and CsPbI₃.

19. The photoelectric conversion element according to claim 3, wherein the photoelectric conversion layer further includes SnF₂.
